(19) United States
(12) Patent Application Publication
(10) Pub. No.: US 2024/0206330 A1
(43) Pub. Date: Jun. 20, 2024

(54) Organic Light Emitting Diode

(71) Applicant: LG Display Co., Ltd., Seoul (KR)

(72) Inventors: Do-Kyun Kwon, Paju-si (KR); Min-Hyeong Hwang, Paju-si (KR); Eun-Jung Park, Paju-si (KR); Yu-Jeong Lee, Paju-si (KR); Hyun-Jin Cho, Paju-si (KR); Jun-Su Ha, Paju-si (KR)

(21) Appl. No.: 18/233,202

(22) Filed: Aug. 11, 2023

(30) Foreign Application Priority Data
Dec. 6, 2022 (KR) 10-2022-0169086

(51) Int. Cl. H10K 85/60; C09K 11/06; H10K 85/30

(52) U.S. Cl. CPC H10K 85/6572; C09K 11/06; H10K 85/342; H10K 85/631; H10K 50/11

(57) ABSTRACT

The present disclosure relates to an organic light emitting diode (OLED) where adjacent emitting material layers includes hosts with different LUMO energy level and/or electron mobility. A first emitting material layer including a first host with relatively slow electron mobility and/or relatively high LUMO energy level is disposed adjacently to a hole transport layer and a second emitting material layer including a second host with relatively fast electron mobility and/or relatively low LUMO energy level is disposed adjacent to an electron transport layer. No exciplex between hole transporting material and the first host is not formed while exciplex between the hole transporting material and the second host is formed so that exciton loss can be minimized. An OLED and an organic light emitting device with low driving voltage and low power consumption and beneficial luminous property and luminous lifetime can be realized.

### CROSS-REFERENCE TO RELATED APPLICATIONS

This application claims the benefit of and the priority of Korean Patent Application No. 10-2022-0169086, filed in the Republic of Korea on Dec. 6, 2022, which is expressly incorporated hereby in its entirety into the present application.

### BACKGROUND

### Technical Field

The present disclosure relates to an organic light emitting diode, and more particularly to, an organic light emitting diode that can implement low power consumption and have improved luminous efficiency and luminous lifespan and an organic light emitting device including thereof.

### Description of the Related Art

A flat display device including an organic light emitting diode (OLED) has attracted attention as a display device that can replace a liquid crystal display device (LCD). The OLED can be formed as a thin organic film less than 2000 Å and the electrode configurations can implement unidirectional or bidirectional images. Also, the OLED can be formed even on a flexible transparent substrate such as a plastic substrate so that a flexible or a foldable display device can be realized with ease using the OLED. In addition, the OLED can be driven at a lower voltage and the OLED has advantageous high color purity compared to the LCD.

Since fluorescent material uses only singlet excitons in the luminous process, the related art fluorescent material shows low luminous efficiency. On the contrary, phosphorescent material can show high luminous efficiency since it uses triplet exciton as well as singlet excitons in the luminous process. However, examples of phosphorescent material include metal complexes, which have a short luminous lifespan for commercial use. There is a need to develop an organic light emitting diode and an organic light emitting device with improved luminous properties and luminous lifetime.

### SUMMARY

Accordingly, embodiments of the present disclosure are directed to an organic light emitting diode and an organic light emitting device that substantially obviate one or more of the problems due to the limitations and disadvantages of the related art.

An aspect of the present disclosure is to provide an organic light emitting diode that implements low power consumption and has improved luminous efficiency and an organic light emitting device including the organic light emitting diode.

Additional features and aspects will be set forth in the description that follows, and in part will be apparent from the description, or may be learned by practice of the disclosed concepts provided herein. Other features and aspects of the disclosed concept may be realized and attained by the structure particularly pointed out in the written description, or derivable therefrom, and the claims hereof as well as the appended drawings.

To achieve these and other advantages and in accordance with objects of the disclosure, as embodied and broadly described herein, in one aspect, the present disclosure provides an organic light emitting diode includes a first electrode; a second electrode facing the first electrode; and an emissive layer disposed between the first and second electrode, and including an emitting material layer, wherein the emitting material layer includes: a first red emitting material layer including a first N-type host; and a second red emitting material layer disposed between the first red emitting material layer and the second electrode, and including a second N-type host, and wherein the second N-type host has a lowest unoccupied molecular orbital (LUMO) energy level lower than a LUMO energy level of the first N-type host.

The second N-type host can have electron mobility larger than an electron mobility of the first N-type host.

The LUMO energy level of the second N-type host can be lower than the LUMO energy level of the first N-type host by about 0.2 eV to about 0.4 eV.

The first N-type host can include an organic compound having the following structure of Chemical Formula 3:

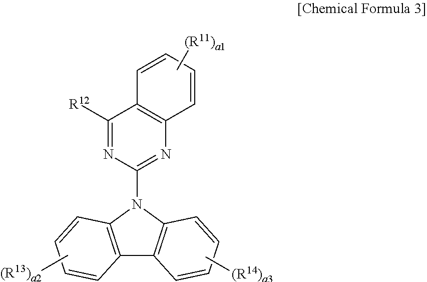

wherein, in the Chemical Formula 3,
R¹¹ is independently an unsubstituted or substituted C₁-C₂₀ alkyl group, an unsubstituted or substituted C₆-C₃₀ aryl group or an unsubstituted or substituted C₃-C₃₀ hetero aryl group, where each R¹¹ is identical to or different from each other when a1 is 2, 3 or 4;
R¹² is hydrogen, an unsubstituted or substituted C₁-C₂₀ alkyl group, an unsubstituted or substituted C₆-C₃₀ aryl group or an unsubstituted or substituted C₃-C₃₀ hetero aryl group;
each of R¹³ and R¹⁴ is independently hydrogen , an unsubstituted or substituted C₆-C₃₀ aryl group or an unsubstituted or substituted C₃-C₃₀ hetero aryl group, where each R¹³ is identical to or different from each other when a2 is 2, 3 or 4 and where each R¹⁴ is identical to or different from each other when a3 is 2, 3 or 4, or
optionally,
two adjacent R¹³ when a2 is 2, 3 or 4 and/or two adjacent R¹⁴ when a3 is 2, 3 or 4 are further linked together to form an unsubstituted or substituted C₆-C₁₀ aromatic ring;
a1 is 0, 1, 2, 3 or 4; and
each of a2 and a3 is independently 0, 1, 2, 3 or 4 where at least one of a2 and a3 is not 0.

The second N-type host can include an organic compound having the following structure of Chemical Formula 5:

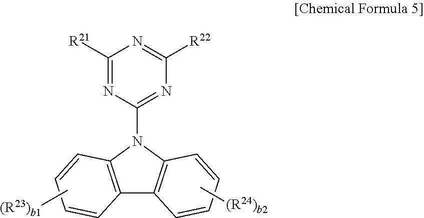

wherein, in the Chemical Formula 5,
each of R²¹ and R²² is independently hydrogen, an unsubstituted or substituted C₁-C₂₀ alkyl group, an unsubstituted or substituted C₆-C₃₀ aryl group or an unsubstituted or substituted C₃-C₃₀ hetero aryl group;
each of R²³ and R²⁴ is independently an unsubstituted or substituted C₁-C₂₀ alkyl group, an unsubstituted or substituted C₆-C₃₀ aryl group or an unsubstituted or substituted C₃-C₃₀ hetero aryl group, where each R²³ is identical to or different from each other when b1 is 2, 3 or 4 and where each R²⁴ is identical to or different from each other when b2 is 2, 3 or 4; and
each of b1 and b2 is independently 0, 1, 2, 3 or 4.

Alternatively, the first red emitting material layer can further include a first P-type host and the second red emitting material layer can further include a second P-type host.

For example, each of the first P-type host and the second P-type host can independently include an organic compound having the following structure of Chemical Formula 1:

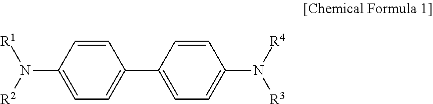

wherein, in the Chemical Formula 1,
each of R¹, R², R³ and R⁴ is independently an unsubstituted or substituted C₆-C₃₀ aryl group or an unsubstituted or substituted C₃-C₃₀ hetero aryl group.

A difference between the LUMO energy level of the first N-type host and a highest occupied molecular orbital (HOMO) energy level of the first P-type host and/or the second P-type host can be between about 2.3 eV and about 2.5 eV.

A difference between the LUMO energy level of the second N-type host and a highest occupied molecular orbital (HOMO) energy level of the first P-type host and/or the second P-type host can be between about 1.8 eV and about 2.2 eV.

Contents of the first N-type host can be larger than contents of the first P-type host in the first red emitting material layer and contents of the second N-type host can be larger than contents of the second P-type host in the second red emitting material layer.

The first red emitting material layer can have a thickness smaller than or equal to a thickness of the second red emitting material layer.

In one example embodiment, the emissive layer can have a single emitting part.

In another example embodiment, the emissive layer can include a first emitting part disposed between the first electrode and the second electrode, and including a first emitting material layer; a second emitting part disposed between the first emitting part and the second electrode, and including a second emitting material layer; and a first charge generation layer disposed between the first emitting part and the second emitting part.

One of the first emitting material layer and the second emitting material layer can include the first red emitting material layer and the second red emitting material layer.

As an example, the second emitting material layer can include a first layer disposed between the first charge generation layer and the second electrode; and a second layer disposed between the first layer and the second electrode, and wherein one of the first layer and the second layer can include the first red emitting material layer and the second red emitting material layer.

For example, first layer can include the first red emitting material layer and the second red emitting material layer.

Optionally, the second emitting material layer can further include a third layer disposed between the first layer and the second layer.

The organic light emitting diode includes two adjacently disposed red emitting material layers each of which includes host with different energy levels and/or electron mobility.

The first red emitting material layer including the first N-type host with relatively high LUMO energy level and relatively low electron mobility is disposed adjacently to the hole transport layer and the second red emitting material layer including the second N-type host with relatively low LUMO energy level and relatively high electron mobility is disposed adjacently to the electron transport layer. No exciplex between the hole transporting material and the first N-type host is formed because the difference between the HOMO energy level of the hole transporting material and the first N-type host in the first red emitting material layer disposed adjacently to the hole transport layer is relatively large. Accordingly, exciton loss outwardly from the emitting material layer can be minimized.

On the contrary, exciplex between the hole transporting material and the second N-type host can be formed because the difference between the HOMO energy level of the hole transporting material and the second N-type host in the second red emitting material layer disposed adjacently to the electron transport layer is relatively small. Accordingly, exciplex can be formed within the emitting material layer. Therefore, an organic light emitting diode and an organic light emitting device with lower driving voltage and low power consumption and beneficial luminous efficiency and luminous lifetime can be realized.

It is to be understood that both the foregoing general description and the following detailed description are merely by way of example and are intended to provide further explanation of the inventive concepts as claimed.

### BRIEF DESCRIPTION OF THE DRAWINGS

The accompanying drawings, which are included to provide a further understanding of the disclosure, are incorporated in and constitute a part of this application, illustrate embodiments of the disclosure and together with the description serve to explain principles of the disclosure.

FIG. 1 illustrates a schematic circuit diagram of an organic light emitting display device in accordance with the present disclosure.

FIG. 2 illustrates a cross-sectional view of an organic light emitting display device as an example of an organic light emitting device in accordance with an example embodiment of the present disclosure.

FIG. 3 illustrates a cross-sectional view of an organic light emitting diode having a single emitting part in accordance with an example embodiment of the present disclosure.

FIG. 4 illustrates a schematic diagram showing energy levels of hole transporting material in a hole transport layer and luminous material in two emitting material layer in accordance with an example embodiment of the present disclosure.

FIG. 5 and FIG. 6 illustrate a schematic diagram showing energy levels of hole transporting material and luminous material in a single emitting material layer.

FIG. 7 illustrates a cross-sectional view of an organic light emitting display device in accordance with another example embodiment of the present disclosure.

FIG. 8 illustrates a cross-sectional view of an organic light emitting diode having a tandem structure of two emitting parts in accordance with another example embodiment of the present disclosure.

FIG. 9 illustrates a cross-sectional view of an organic light emitting diode having a tandem structure of three emitting parts in accordance with another example embodiment of the present disclosure.

FIG. 10 illustrates a cross-sectional view of an organic light emitting diode having a tandem structure of four emitting parts in accordance with another example embodiment of the present disclosure.

FIGS. 11 and 12 illustrate photoluminescence (PL) spectra of a host or a combination of host in a single emitting material layer in accordance with Comparative Examples.

FIG. 13 illustrates electroluminescence (EL) spectra of an organic light emitting diodes fabricated in Examples and Comparative Examples.

FIG. 14 illustrates J-V curve of an organic light emitting diodes fabricated in Examples and Comparative Examples.

### DETAILED DESCRIPTION

Reference will now be made in detail to aspects of the disclosure, examples of which are illustrated in the accompanying drawings. Wherever possible, the same reference numbers will be used throughout the drawings to refer to the same or like parts.

The present disclosure relates to an organic emitting diode and/or an organic light emitting device where an emissive layer includes plural emitting material layers including compounds with controlled energy levels and/or electron mobility so as to lower driving voltage and improve luminous efficiency and luminous lifetime thereof. As an example, the emissive layer can be applied to an organic light emitting diode with single emitting unit in a red pixel region. Alternatively, the emissive layer can be applied to an organic light emitting diode having a tandem structure where two or more emitting parts are stacked. The organic light emitting diode can be applied to an organic light emitting device such as an organic light emitting display device or an organic light emitting illumination device.

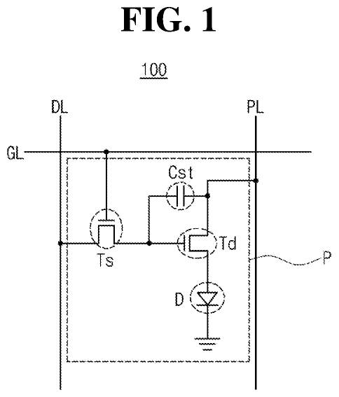

FIG. 1 illustrates a schematic circuit diagram of an organic light emitting display device in accordance with the present disclosure. As illustrated in FIG. 1, a gate line GL, a data line DL and power line PL, each of which crosses each other to define a pixel region P, in an organic light emitting display device 100. A switching thin film transistor Ts, a driving thin film transistor Td, a storage capacitor Cst and an organic light emitting diode D are disposed within the pixel region P. The pixel region P can include a red (R) pixel region, a green (G) pixel region and a blue (B) pixel region. However, embodiments of the present disclosure are not limited to such examples.

The switching thin film transistor Ts is connected to the gate line GL and the data line DL. The driving thin film transistor Td and the storage capacitor Cst are connected between the switching thin film transistor Ts and the power line PL. The organic light emitting diode D is connected to the driving thin film transistor Td. When the switching thin film transistor Ts is turned on by a gate signal applied to the gate line GL, a data signal applied to the data line DL is applied to a gate electrode of the driving thin film transistor Td and one electrode of the storage capacitor Cst through the switching thin film transistor Ts.

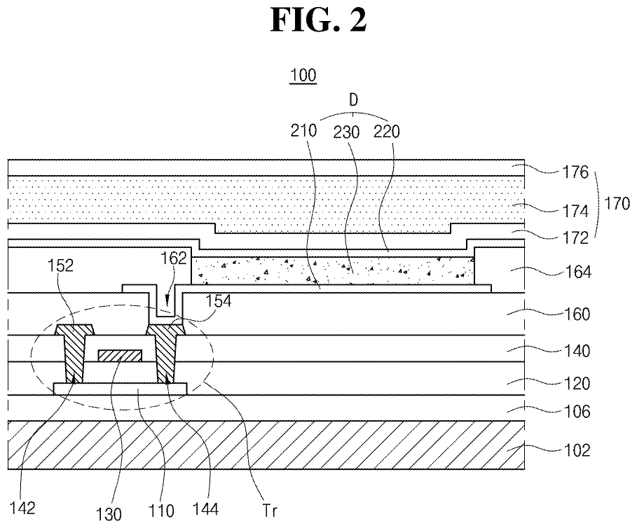

The driving thin film transistor Td is turned on by the data signal applied to the gate electrode 130 (FIG. 2) so that a current proportional to the data signal is supplied from the power line PL to the organic light emitting diode D through the driving thin film transistor Td. And then, the organic light emitting diode D emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the organic light emitting display device can display a desired image.

FIG. 2 illustrates a schematic cross-sectional view of an organic light emitting display device in accordance with an example embodiment of the present disclosure. As illustrated in FIG. 2, the organic light emitting display device 100 includes a substrate 102, a thin-film transistor Tr on the substrate 102, and an organic light emitting diode (OLED) D connected to the thin film transistor Tr. As an example, the substrate 102 can include a red pixel region, a green pixel region and a blue pixel region and an OLED D can be located in each pixel region. Each of the OLED D emitting red, green and blue light, respectively, is located correspondingly in the red pixel region, the green pixel region and the blue pixel region. As an example, the organic light emitting diode D can be located in the red pixel region.

The substrate 102 can include, but is not limited to, glass, thin flexible material and/or polymer plastics. For example, the flexible material can be selected from the group, but is not limited to, polyimide (PI), polyethersulfone (PES), polyethylenenaphthalate (PEN), polyethylene terephthalate (PET), polycarbonate (PC) and/or combinations thereof. The substrate 102, on which the thin film transistor Tr and the organic light emitting diode D are arranged, forms an array substrate.

A buffer layer 106 can be disposed on the substrate 102. The thin film transistor Tr can be disposed on the buffer layer 106. The buffer layer 106 can be omitted.

A semiconductor layer 110 is disposed on the buffer layer 106. In one example embodiment, the semiconductor layer 110 can include, but is not limited to, oxide semiconductor materials. In this case, a light-shield pattern may be disposed under the semiconductor layer 110, and the light-shield pattern can prevent light from being incident toward the semiconductor layer 110, and thereby, preventing or reducing the semiconductor layer 110 from being degraded by the light. Alternatively, the semiconductor layer 110 can include polycrystalline silicon. In this case, opposite edges of the semiconductor layer 110 can be doped with impurities.

A gate insulating layer 120 including an insulating material is disposed on the semiconductor layer 110. The gate insulating layer 120 can include, but is not limited to, an inorganic insulating material such as silicon oxide (SiOₓ, wherein 0<x≤2) or silicon nitride (SiNₓ, wherein 0<x≤2).

A gate electrode 130 made of a conductive material such as a metal is disposed on the gate insulating layer 120 so as to correspond to a center of the semiconductor layer 110. While the gate insulating layer 120 is disposed on a whole area of the substrate 102 as shown in FIG. 2, the gate insulating layer 120 may be patterned identically as the gate electrode 130.

An interlayer insulating layer 140 including an insulating material is disposed on the gate electrode 130 and covers an entire surface of the substrate 102. The interlayer insulating layer 140 can include, but is not limited to, an inorganic insulating material such as silicon oxide (SiOₓ, wherein 0<x≤2) or silicon nitride (SiNₓ, wherein 0<x≤2), or an organic insulating material such as benzocyclobutene or photo-acryl.

The interlayer insulating layer 140 has first and second semiconductor layer contact holes 142 and 144 that expose or do not cover a portion of the surface nearer to the opposing ends than to a center of the semiconductor layer 110. The first and second semiconductor layer contact holes 142 and 144 are disposed on opposite sides of the gate electrode 130 and spaced apart from the gate electrode 130. The first and second semiconductor layer contact holes 142 and 144 are formed within the gate insulating layer 120 and the interlayer insulating layer 140 in FIG. 2. Alternatively, the first and second semiconductor layer contact holes 142 and 144 can be formed only within the interlayer insulating layer 140 when the gate insulating layer 120 is patterned identically as the gate electrode 130.

A source electrode 152 and a drain electrode 154, which are made of conductive material such as a metal, are disposed on the interlayer insulating layer 140. The source electrode 152 and the drain electrode 154 are spaced apart from each other on opposing sides of the gate electrode 130, and contact both sides of the semiconductor layer 110 through the first and second semiconductor layer contact holes 142 and 144, respectively.

The semiconductor layer 110, the gate electrode 130, the source electrode 152 and the drain electrode 154 constitute the thin film transistor Tr, which acts as a driving element. The thin film transistor Tr in FIG. 2 has a coplanar structure in which the gate electrode 130, the source electrode 152 and the drain electrode 154 are disposed on the semiconductor layer 110. Alternatively, the thin film transistor Tr can have an inverted staggered structure in which a gate electrode is disposed under a semiconductor layer and a source and drain electrodes are disposed on the semiconductor layer. In this case, the semiconductor layer can include amorphous silicon.

The gate line GL and the data line DL, which cross each other to define a pixel region P. and a switching clement Ts, which is connected to the gate line GL and the data line DL, can be further formed in the pixel region P. The switching element Ts is connected to the thin film transistor Tr, which is a driving element. In addition, the power line PL is spaced apart in parallel from the gate line GL or the data line DL. The thin film transistor Tr may further include a storage capacitor Cst configured to constantly keep a voltage of the gate electrode 130 for one frame.

A passivation layer 160 is disposed on the source and drain electrodes 152 and 154. The passivation layer 160 covers the thin film transistor Tr on the whole substrate 102. The passivation layer 160 has a flat top surface and a drain contact hole 162 that exposes or does not cover the drain electrode 154 of the thin film transistor Tr. While the drain contact hole 162 is disposed on the second semiconductor layer contact hole 144, it may be spaced apart from the second semiconductor layer contact hole 144.

The organic light emitting diode (OLED) D includes a first electrode 210 that is disposed on the passivation layer 160 and connected to the drain electrode 154 of the thin film transistor Tr. The OLED D further includes an emissive layer 230 and a second electrode 220 each of which is disposed sequentially on the first electrode 210.

The first electrode 210 is disposed separately in cach pixel region. The first electrode 210 can be an anode and include conductive material having relatively high work function value. For example, the first electrode 210 can include a transparent conductive oxide (TCO). More particularly, the first electrode 210 can include, but is not limited to, indium tin oxide (ITO), indium zinc oxide (IZO), indium tin zinc oxide (ITZO), tin oxide (SnO), zinc oxide (ZnO), indium cerium oxide (ICO), aluminum doped zinc oxide (AZO), and/or combinations thereof.

In one example embodiment, when the organic light emitting display device 100 is a bottom-emission type, the first electrode 210 can have a single-layered structure of the TCO. Alternatively, when the organic light emitting display device 100 is a top-emission type, a reflective electrode or a reflective layer may be disposed under the first electrode 210. For example. the reflective electrode or the reflective layer can include, but is not limited to, silver (Ag) or aluminum-palladium-copper (APC) alloy. In the OLED D of the top-emission type, the first electrode 210 can have a triple-layered structure of ITO/Ag/ITO or ITO/APC/ITO.

In addition, a bank layer 164 is disposed on the passivation layer 160 in order to cover edges of the first electrode 210. The bank layer 164 exposes or does not cover a center of the first electrode 210 corresponding to each pixel region. The bank layer 164 may be omitted.

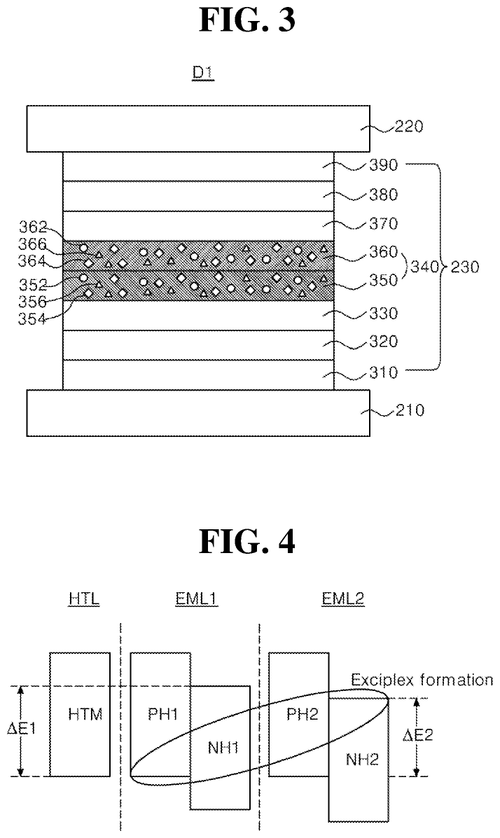

An emissive layer 230 is disposed on the first electrode 210. In one example embodiment, the emissive layer 230 can have a single-layered structure of an emitting material layer (EML). Alternatively, the emissive layer 230 can have a multiple-layered structure of a hole injection layer (HIL), a hole transport layer (HTL), an electron blocking layer (EBL), an EML, a hole blocking layer (HBL), an electron transport layer (ETL), an electron injection layer (EIL) and/or a charge generation layer (CGL) (FIG. 3). In one aspect, the emissive layer 230 can have a single emitting part. Alternatively, the emissive layer 230 can have multiple emitting parts to form a tandem structure. The emissive layer can include plural red emitting material layers each of which includes a host with controlled energy levels and/or electron mobility.

The second electrode 220 is disposed on the substrate 102 above which the emissive layer 230 is disposed. The second electrode 220 can be disposed on a whole display area. The second electrode 220 can include a conductive material with a relatively low work function value compared to the first electrode 210. The second electrode 220 can be a cathode providing electrons. For example, the second electrode 220 can include at least one of, but is not limited to, aluminum (Al), magnesium (Mg), calcium (Ca), silver (Ag), alloy thereof and/or combinations thereof such as aluminum-magnesium alloy (Al—Mg). When the organic light emitting display device 100 is a top-emission type, the second electrode 220 is thin so as to have light-transmissive (semi-transmissive) property.

In addition, an encapsulation film 170 can be disposed on the second electrode 220 in order to prevent or reduce outer moisture from penetrating into the OLED D. The encapsulation film 170 can have, but is not limited to, a laminated structure of a first inorganic insulating film 172, an organic insulating film 174 and a second inorganic insulating film 176. The encapsulation film 170 can be omitted.

A polarizing plate can be attached onto the encapsulation film 170 to reduce reflection of external light. For example, the polarizing plate may be a circular polarizing plate. When the organic light emitting display device 100 is a bottom-emission type, the polarizing plate can be disposed under the substrate 102. Alternatively, when the organic light emitting display device 100 is a top-emission type, the polarizing plate can be disposed on the encapsulation film 170. In addition, a cover window can be attached to the encapsulation film 170 or the polarizing plate. In this case, the substrate 102 and the cover window may have a flexible property, thus the organic light emitting display device 100 may be a flexible display device.

The OLED D is described in more detail. FIG. 3 illustrates a schematic cross-sectional view of an organic light emitting diode having a single emitting part in accordance with an example embodiment of the present disclosure.

As illustrated in FIG. 3, the organic light emitting diode (OLED) D1 in accordance with the present disclosure includes first and second electrodes 210 and 220 facing each other and an emissive layer 230 disposed between the first and second electrodes 210 and 220. The organic light emitting display device 100 includes a red pixel region, a green pixel region and a blue pixel region, and the OLED D1 can be disposed in the red pixel region.

In an example embodiment, the emissive layer 230 includes an emitting material layer (EML) 340 disposed between the first and second electrodes 210 and 220. Also, the emissive layer 230 can include at least one of a hole transport layer (HTL) 320 disposed between the first electrode 210 and the EML 340 and an electron transport layer (ETL) 380 disposed between the second electrode 220 and the EML 340. In addition, the emissive layer 230 can further include at least one of a hole injection layer (HIL) 310 disposed between the first electrode 210 and the HTL 320 and an electron injection layer (EIL) 390 disposed between the second electrode 220 and the ETL 380. Alternatively, the emissive layer 230 can further comprise a first exciton blocking layer, i.e. an electron blocking layer (EBL) 330 disposed between the HTL 320 and the EML 340 and/or a second exciton blocking layer, i.e. a hole blocking layer (HBL) 370 disposed between the EML 340 and the ETL 380.

The first electrode 210 can be an anode that provides a hole into the EML 340. The first electrode 210 can include a conductive material having a relatively high work function value, for example, a transparent conductive oxide (TCO). In an example embodiment, the first electrode 210 can include, but is not limited to, ITO, IZO, ITZO, SnO, ZnO, ICO, AZO, and/or combinations thereof.

The second electrode 220 can be a cathode that provides an electron into the EML 340. The second electrode 220 can include a conductive material having a relatively low work function values, i.e., a highly reflective material such as Al, Mg, Ca, Ag, and/or alloy thereof and/or combinations thereof such as Al—Mg. For example, each of the first electrode 210 and the second electrode 220 can have, but is not limited to, a thickness of about 10 nm to about 300 nm.

The EML 340 includes a first red emitting material layer (R-EML1) 350 and a second red emitting material layer (R-EML2) 360 disposed between the R-EML1 350 and the second electrode 220. The R-EML1 350 includes a first N-type host (first electron-type host, first compound) 352, and optionally, a first P-type host (first hole-type host, second compound) 354 and/or a first red dopant (first red emitter, third compound) 356. The R-EML2 360 includes a second N-type host (second electron-type host, fourth compound) 362, and optionally, a second P-type host (second hole-type host, fifth compound) 364 and/or a second red dopant (second red emitter, sixth compound) 366. Substantial or ultimate emission is occurred at the first red dopant 356 and the second red dopant 366 in the R-EML1 350 and the R-EML2 360, respectively.

Each of the first P-type host 354 and the second P-type host 364 has excellent affinity to holes compared to each of the first N-type host 352 and the second N-type host 362, respectively. Each of the first N-type 352 and the second N-type host 362 has excellent affinity to electrons compared to each of the first P-type host 354 and the second P-type host 364, respectively.

In one example embodiment, each of the first P-type host 354 and the second P-type host 364 can be independently an aromatic amine compound and/or a hetero aromatic amine compound. As an example, each of the first P-type host 354 and the second P-type host 364 can independently include an organic compound having the following structure of Chemical Formula 1:

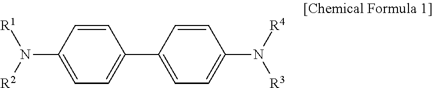

wherein, in the Chemical Formula 1,
each of R¹, R², R³ and ⁴ is independently an unsubstituted or substituted C₆-C₃₀ aryl group or an unsubstituted or substituted C₃-C₃₀ hetero aryl group.

As used herein, the term “unsubstituted” means that hydrogen is directly linked to a carbon atom. “Hydrogen”, as used herein, may refer to protium, deuterium and tritium.

As used herein, “substituted” means that the hydrogen is replaced with a substituent. The substituent can comprise, but is not limited to, an unsubstituted or halogen-substituted C₁-C₂₀ alkyl group, an unsubstituted or halogen-substituted C₁-C₂₀ alkoxy, halogen, a cyano group, a hydroxyl group, a carboxylic group, a carbonyl group, an amino group, a C₁-C₁₀ alkyl amino group, a C₆-C₃₀ aryl amino group, a C₃-C₃₀ hetero aryl amino group, a nitro group, a hydrazyl group, a sulfonate group, a C₁-C₁₀ alkyl silyl group, a C₁-C₁₀ alkoxy silyl group, a C₃-C₂₀ cycloalkyl silyl group, a C₆-C₃₀ aryl silyl group, a C₃-C₃₀ hetero aryl silyl group, an unsubstituted or substituted C₆-C₃₀ aryl group, an unsubstituted or substituted C₃-C₃₀ hetero aryl group.

As used herein, the term “hetero” in terms such as “a hetero aryl group”, and “a hetero arylene group” and the likes means that at least one carbon atom, for example 1 to 5 carbons atoms, constituting an aliphatic chain, an alicyclic group or ring or an aromatic group or ring is substituted with at least one hetero atom selected from the group consisting of N, O, S and P.

The aryl group can independently include, but is not limited to, an unfused or fused aryl group such as phenyl, biphenyl, terphenyl, naphthyl, anthracenyl, pentalenyl, indenyl, indeno-indenyl, heptalenyl, biphenylenyl, indacenyl, phenalenyl, phenanthrenyl, benzo-phenanthrenyl, dibenzo-phenanthrenyl, azulenyl, pyrenyl, fluoranthenyl, triphenylenyl, chrysenyl, tetraphenylenyl, tetracenyl, pleiadenyl, picenyl, pentaphenylenyl, pentacenyl, fluorenyl, indeno-fluorenyl or spiro-fluorenyl.

The hetero aryl group can independently include, but is not limited to, an unfused or fused hetero aryl group such as pyrrolyl, pyridinyl, pyrimidinyl, pyrazinyl, pyridazinyl, triazinyl, tetrazinyl, imidazolyl, pyrazolyl, indolyl, iso-indolyl, indazolyl, indolizinyl, pyrrolizinyl, carbazolyl, benzo-carbazolyl, dibenzo-carbazolyl, indolo-carbazolyl, indeno-carbazolyl, benzo-furo-carbazolyl, benzo-thieno-carbazolyl, carbolinyl, quinolinyl, iso-quinolinyl, phthalazinyl, quinoxalinyl, cinnolinyl, quinazolinyl, quinolizinyl, purinyl, benzo-quinolinyl, benzo-iso-quinolinyl, benzo-quinazolinyl, benzo-quinoxalinyl, acridinyl, phenazinyl, phenoxazinyl, phenothiazinyl, phenanthrolinyl, perimidinyl, phenanthridinyl, pteridinyl, naphthyridinyl, furanyl, pyranyl, oxazinyl, oxazolyl, oxadiazolyl, triazolyl, dioxinyl, benzo-furanyl, dibenzo-furanyl, thiopyranyl, xanthenyl, chromenyl, iso-chromenyl, thiazinyl, thiophenyl, benzo-thiophenyl, dibenzo-thiophenyl, difuro-pyrazinyl, benzofuro-dibenzo-furanyl, benzothieno-benzo-thiophenyl, benzothieno-dibenzo-thiophenyl, benzothieno-benzo-furanyl, benzothieno-dibenzo-furanyl, xanthene-linked spiro acridinyl, dihydroacridinyl substituted with at least one C₁-C₁₀ alkyl and N-substituted spiro fluorenyl.

As an example, each of the aromatic group (or aryl group) or the hetero aromatic group (or hetero aryl group) can consist of one to four aromatic and/or hetero aromatic rings. When the number of the aromatic and/or hetero aromatic rings of R¹ to R⁴ becomes more than four, conjugated structure among the within the whole molecule becomes too long, thus, the organic compound can have too narrow energy bandgap. For example, the aryl group and the hetero aryl group can comprise, but is not limited to, phenyl, biphenyl, naphthyl, anthracenyl, pyrrolyl, triazinyl, imidazolyl, pyrazolyl, pyridinyl, pyrazinyl, pyrimidinyl, pyridazinyl, furanyl, benzo-furanyl, dibenzo-furanyl, thiophenyl, benzo-thiophenyl, dibenzo-thiophenyl, carbazolyl, acridinyl, carbolinyl, phenazinyl, phenoxazinyl, or phenothiazinyl.

For example, each of R¹, R², R³ and R⁴ in Chemical Formula 1 can be, but is not limited to, phenyl, naphthyl, biphenyl and/or fluorenyl each of which is independently unsubstituted or substituted with at least one group of a C₁-C₁₀ alkyl group, a C₆-C₂₀ aryl group and a C₃-C₂₀ hetero aryl group. As an example, each of the first P-type host 354 and the second P-type host 364 can be independently, but is not limited to, at least one of the following compounds of Chemical Formula 2:

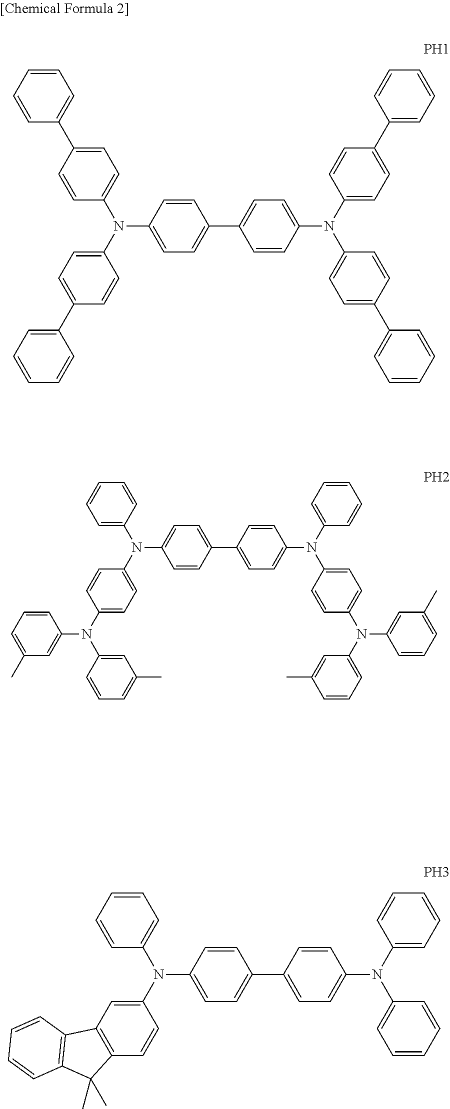 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Cc1cccc(N(c2ccc(N(c3ccccc3)c3ccc(-c4ccc(N(c5ccccc5)c5ccc(N(c6cccc(C)c6)c6cccc(C)c6)cc5)cc4)cc3)cc2)c2cccc(C)c2)c1 ; CC1(C)c2ccccc2-c2cc(N(c3ccccc3)c3ccc(-c4ccc(N(c5ccccc5)c5ccccc5)cc4)cc3)ccc21]

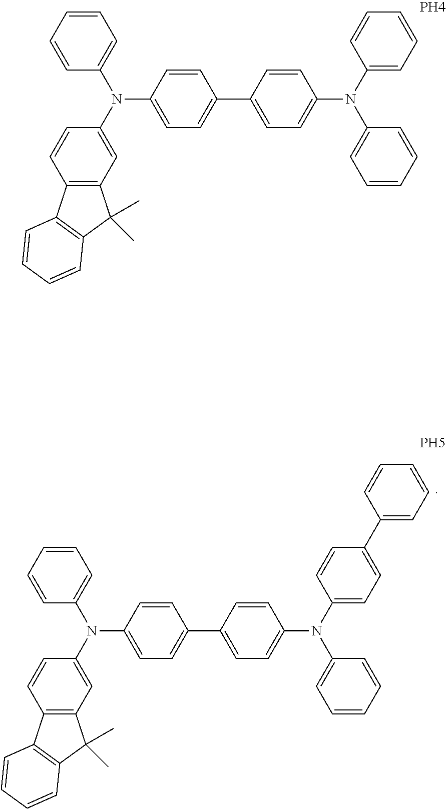 [SMILES: CC1(C)c2ccccc2-c2ccc(N(c3ccccc3)c3ccc(-c4ccc(N(c5ccccc5)c5ccccc5)cc4)cc3)cc21 ; CC1(C)c2ccccc2-c2ccc(N(c3ccccc3)c3ccc(-c4ccc(N(c5ccccc5)c5ccc(-c6ccccc6)cc5)cc4)cc3)cc21]

The first P-type host 354 can be identical to or different from the second P-type host 364.

The second N-type host 362 can have highest occupied molecular orbital (HOMO) energy level lower (deeper) that HOMO energy level of the first N-type host 352. Alternatively, the second N-type host 362 can have electron mobility greater than electron mobility of the first N-type host 352. In this case, holes and electrons can be injected in balance into the EML 340. It is possible to minimize exciton loss outwardly from the EML 340 and to recombine excitons efficiently within the EML 340.

As an example, the first N-type host 352 can include a quinazoline-based organic compound. The first N-type host 352 can include an organic compound having the following structure of Chemical Formula 3:

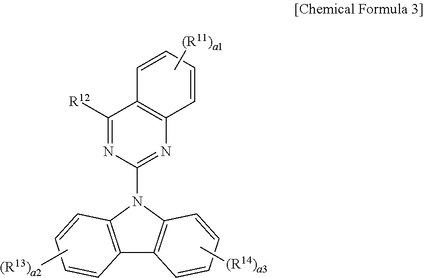

wherein, in the Chemical Formula 3,
R¹¹ is independently an unsubstituted or substituted C₁-C₂₀ alkyl group, an unsubstituted or substituted C₆-C₃₀ aryl group or an unsubstituted or substituted C₃-C₃₀ hetero aryl group, where each R¹¹ is identical to or different from each other when a1 is 2, 3 or 4;
R¹² is hydrogen, an unsubstituted or substituted C₁-C₂₀ alkyl group, an unsubstituted or substituted C₆-C₃₀ aryl group or an unsubstituted or substituted C₃-C₃₀ hetero aryl group;
each of R¹³ and R¹⁴ is independently hydrogen, an unsubstituted or substituted C₆-C₃₀ aryl group or an unsubstituted or substituted C₃-C₃₀ hetero aryl group, where each R¹³ is identical to or different from each other when a2 is 2, 3 or 4 and where each R¹⁴ is identical to or different from each other when a3 is 2, 3 or 4, or
optionally,
two adjacent R¹³ when a2 is 2, 3 or 4 and/or two adjacent R¹⁴ when a3 is 2, 3 or 4 are further linked together to form an unsubstituted or substituted C₆-C₁₀ aromatic ring;
a1 is 0, 1, 2, 3 or 4; and
each of a2 and a3 is independently 0, 1, 2, 3 or 4 where at least one of a2 and a3 is not 0.

For example, R¹¹ can be hydrogen, R¹² can be phenyl, R¹³ can be hydrogen, phenyl or naphthyl, or two adjacent R¹³ can further linked to form a benzene ring, and R¹⁴ can be carbazolyl or benzo-carbazolyl in Chemical Formula 3. Each of the carbazolyl and the benzo-carbazolyl of R¹⁴ can be independently unsubstituted or substituted with phenyl and/or naphthyl each of which can be independently unsubstituted or further substituted with other phenyl and/or naphthyl. As an example, the first N-type host 352 can be, but is not limited to, at least one of the following compound of Chemical Formula 4:

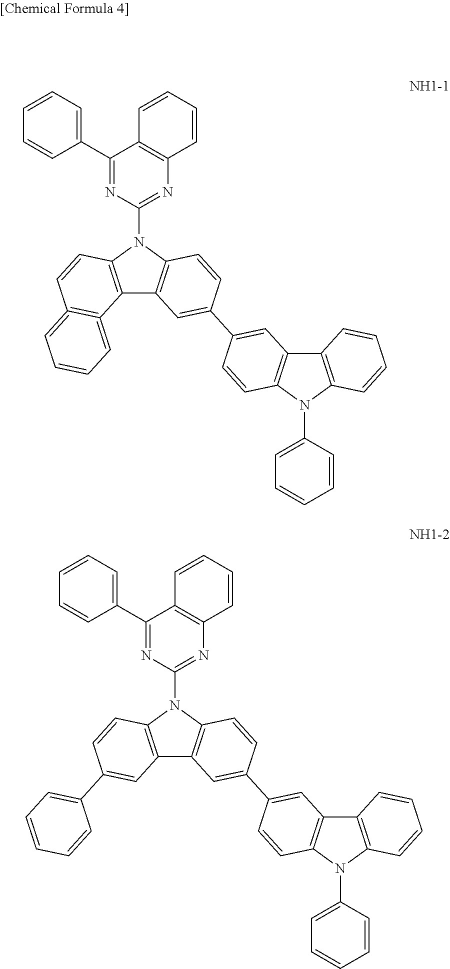

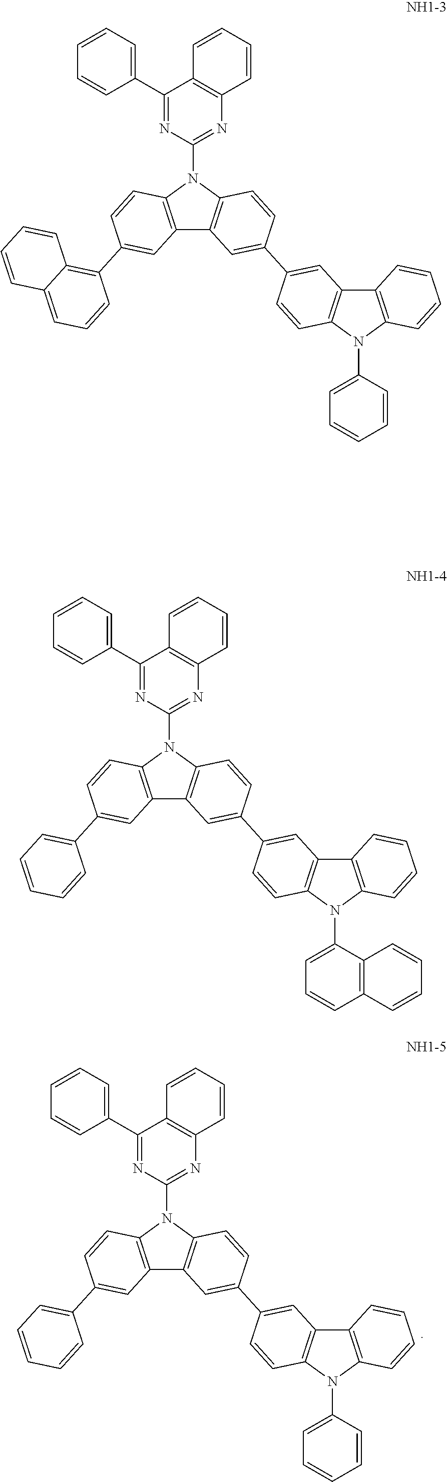 [SMILES: c1ccc(-c2nc(-n3c4ccc(-c5ccc6c(c5)c5ccccc5n6-c5ccccc5)cc4c4cc(-c5cccc6ccccc56)ccc43)nc3ccccc23)cc1 ; c1ccc(-c2ccc3c(c2)c2cc(-c4ccc5c(c4)c4ccccc4n5-c4cccc5ccccc45)ccc2n3-c2nc(-c3ccccc3)c3ccccc3n2)cc1 ; c1ccc(-c2ccc3c(c2)c2cc(-c4ccc5c(c4)c4ccccc4n5-c4ccccc4)ccc2n3-c2nc(-c3ccccc3)c3ccccc3n2)cc1]

As an example, the second N-type host 362 can include a triazine-based organic compound. The second N-type host 362 can include an organic compound having the following structure of Chemical Formula 5:

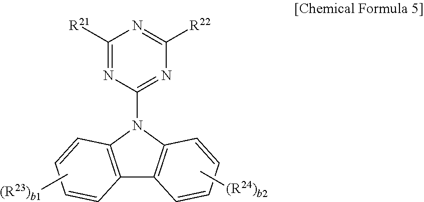

wherein, in the Chemical Formula 5,
each of R²¹ and R²² is independently hydrogen, an unsubstituted or substituted C₁-C₂₀ alkyl group, an unsubstituted or substituted C₆-C₃₀ aryl group or an unsubstituted or substituted C₃-C₃₀ hetero aryl group;
each of R²³ and R²⁴ is independently an unsubstituted or substituted C₁-C₂₀ alkyl group, an unsubstituted or substituted C₆-C₃₀ aryl group or an unsubstituted or substituted C₃-C₃₀ hetero aryl group, where each R²³ is identical to or different from each other when b1 is 2, 3 or 4 and where each R²⁴ is identical to or different from each other when b2 is 2, 3 or 4; and
each of b1 and b2 is independently 0, 1, 2, 3 or 4.

For example, each of R²¹ and R²² can be phenyl, naphthyl (e.g., 1-naphthyl or 2-naphthyl) or biphenyl, R²³ can be hydrogen and R²⁴ can be carbazolyl or benzo-carbazolyl in Chemical Formula 5. Each of the carbazolyl and the benzo-carbazolyl of R²⁴ can be independently unsubstituted or substituted with phenyl and/or naphthyl each of which can be independently unsubstituted or further substituted with other phenyl and/or naphthyl. As an example, the second N-type host 362 can be, but is not limited to, at least one of the following compound of Chemical Formula 6:

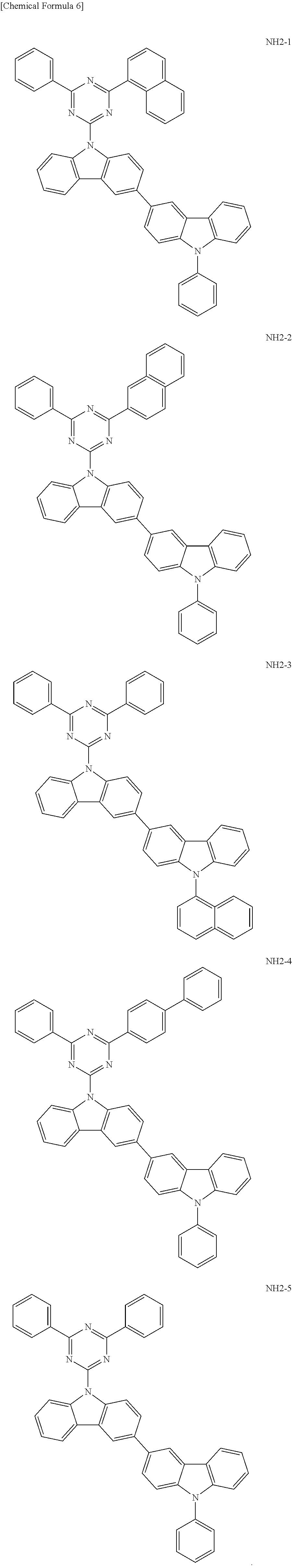

Each of the first red dopant 356 and the second red dopant 366 can independently include at least one of red phosphorescent material, red fluorescent material, and red delayed fluorescent material.

In one example embodiment, each of the first red dopant 356 and the second red dopant 366 can independently include, but is not limited to, Bis[2-(4,6-dimethyl) phenylquinoline)](2,2,6,6-tetramethylheptane-3,5-dionate)iridium(III), Bis[2-(4-n-hexylphenyl)quinoline](acetylacetonate)iridium(III) (Hex-Ir(phq)₂(acac)), Tris[2-(4-n-hexylphenyl)quinoline]iridium(III) (Hex-Ir(phq)₃), Tris[2-phenyl-4-methylquinoline]iridium(III) (Ir(Mphq)₃), Bis(2-phenylquinoline)(2,2,6,6-tetramethylheptene-3,5-dionate)iridium(III) (Ir(dpm)PQ₂), Bis(phenylisoquinoline)(2,2,6,6-tetramethylheptene-3,5-dionate)iridium(III) (Ir(dpm)(piq)₂), Bis(1-phenylisoquinoline)(acetylacetonate)iridium(III) (Ir(piq)₂(acac)), Bis[(4-n-hexylphenyl)isoquinoline](acetylacetonate)iridium(III) (Hex-Ir(piq)₂(acac)), Tris[2-(4-n-hexylphenyl)quinoline]iridium(III) (Hex-Ir(piq)₃), Tris(2-(3-methylphenyl)-7-methyl-quinolato)iridium (Ir(dmpq)₃), Bis[2-(2-methylphenyl)-7-methyl-quinoline](acetylacetonate) iridium(III) (Ir(dmpq)₂(acac)), Bis[2-(3,5-dimethylphenyl)-4-methyl-quinoline](acetylacetonate)iridium(III) (Ir(mphmq)₂(acac)), Tris(dibenzoylmethane)mono(1,10-phenanthroline)europium(III) (Eu(dbm)₃(phen)) and/or combinations thereof.

In another example embodiment, each of the first red dopant 356 and the second red dopant 366 can independently include, but is not limited to, a phosphorescent compound having the following structure of Chemical Formula 7:

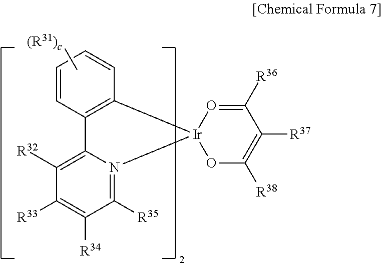

wherein, in Chemical Formula 7,
R³¹ is halogen, an unsubstituted or substituted C₁-C₂₀ alkyl group, an unsubstituted or substituted C₃-C₂₀ cycloalkyl group, an unsubstituted or substituted C₆-C₃₀ aryl group or an unsubstituted or substituted C₃-C₃₀ hetero aryl group, where R³¹ is identical to or different from each other when c is 2, 3 or 4;
each of R³², R³³, R³⁴ and R³⁵ is independently hydrogen, halogen, an unsubstituted or substituted C₁-C₂₀ alkyl group, an unsubstituted or substituted C₃-C₂₀ cycloalkyl group, an unsubstituted or substituted C₆-C₃₀ aryl group or an unsubstituted or substituted C₃-C₃₀ hetero aryl group, or
optionally,
two adjacent groups among R³², R³³, R³⁴ and R³⁵ are further linked together to form an unsubstituted or substituted C₆-C₁₀ aromatic ring;
each of R³⁶, R³⁷ and R³⁸ is independently hydrogen or an unsubstituted or substituted C₁-C₂₀ alkyl group;
c is 0, 1, 2, 3 or 4.

For example, R³¹ can be hydrogen or an unsubstituted or substituted C₁-C₁₀ alkyl group, each of R³², R³³, R³⁴ and R³⁵ can be independently hydrogen, or two groups among R³², R³³, R³⁴ and R³⁵ can be further linked to form an unsubstituted or substituted benzene ring in Chemical Formula 7. As an example, each of the first red dopant 356 and the second red dopant 366 can independently include, but is not limited to, a red phosphorescent compound having the following structure of Chemical Formula 8:

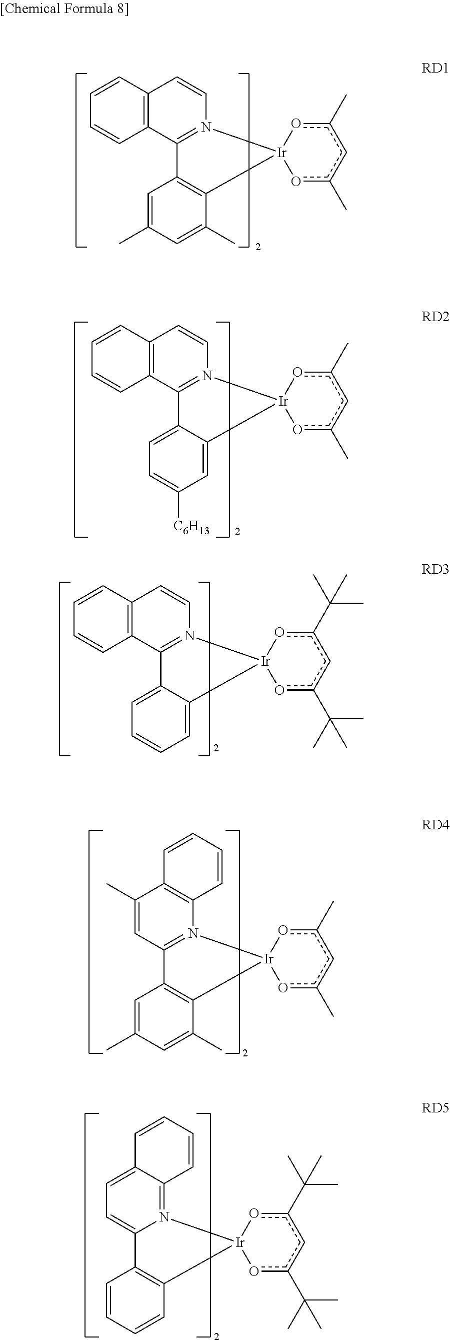

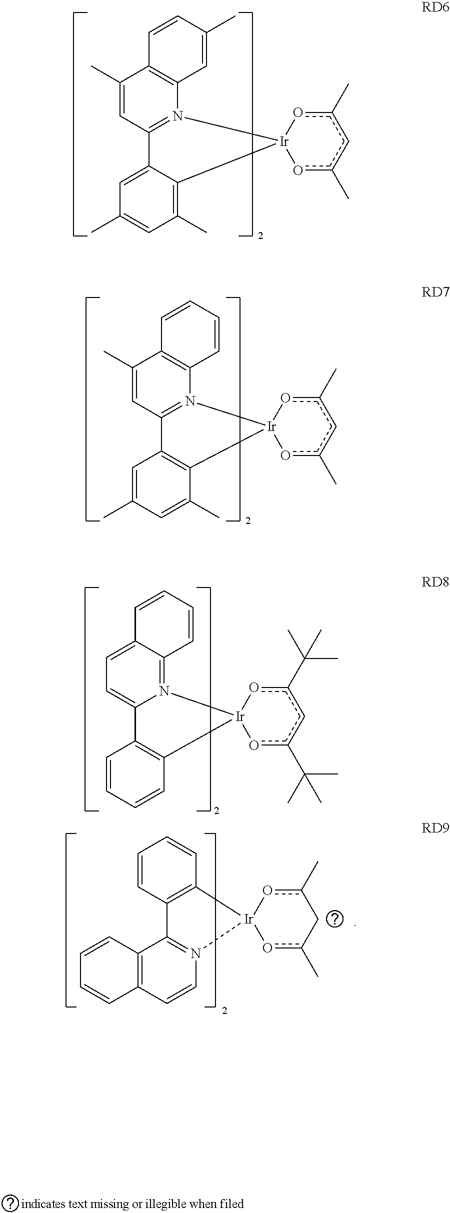

The first red dopant 356 can be identical to or different from the second red dopant 366.

As described above, the second N-type host 362 has LUMO energy level lower than the LUMO energy level of the first N-type host 352 and excellent electron mobility superior to the first N-type host 352. In this case, the luminous efficiency in the EML 340 can be improved.

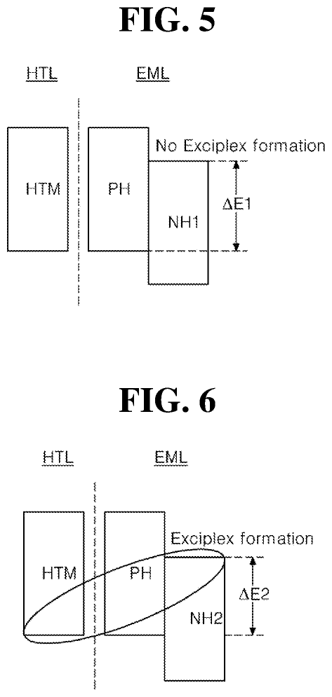

FIG. 4 illustrates a schematic diagram showing energy levels of hole transporting material in a hole transport layer and luminous material in two emitting material layer in accordance with an example embodiment of the present disclosure.

As illustrated in FIGS. 3 and 4, a difference ΔE1 between HOMO energy level of the first P-type host 354 (PH1) which can be utilized as hole transporting material HTM in the HTL 320 and the LUMO energy level of the first N-type host 352 (NH1) with relatively high (shallow) LUMO energy level is relatively wide. Accordingly, there may be no exciplex between the first P-type host 354 (PH1) in the R-EML1 350 (EML1) and the first N-type host 352 (NH1). Accordingly, exciton loss outwardly from the EML 340 can be minimized or reduced.

On the contrary, a difference ΔE2 between the HOMO energy level of the second P-type host 364 (PH2) and the LUMO energy level of the second N-type host 362 (NH2) with relatively low (deep) LUMO energy level in the R-EML2 360 (EML2) is relatively narrow. In this case, exciplex between the second P-type host 364 (PH2) and the second N-type host 362 (NH2) in the R-EML2 360 (EML2) can be formed. In other words, it is possible to induce the formation of the exciplex within the EML 340. Accordingly, it is possible to minimize exciton loss outwardly from the EML 340, and to reduce driving voltage and power consumption by inducing the exciplex formation within the EML 340.

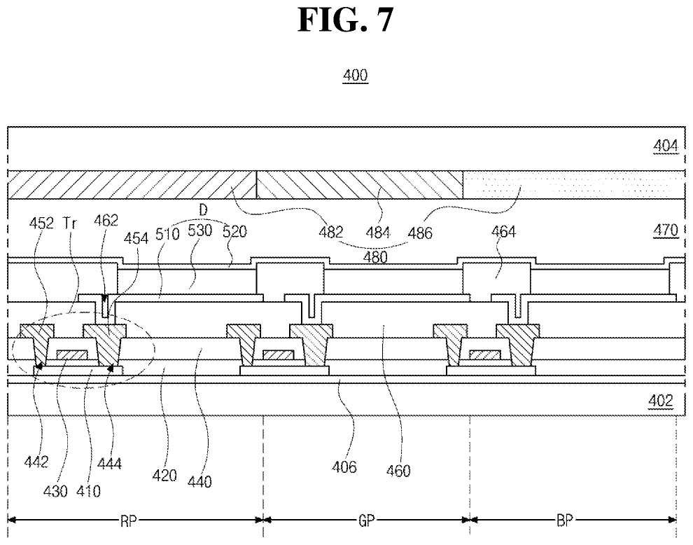

On the other hand, as illustrated in FIG. 5, when the single emitting material layer includes the P-type host PH and the first N-type host NH1 with relatively shallow LUMO energy level, no exciplex is formed between the HOMO energy level of the P-type host PH and the LUMO energy level of the first N-type host NH1. In this case, it is difficult to enhance the luminous efficiency of an organic light emitting diode, and the driving voltage of the organic light emitting diode can be increased, and the lifetime of the diode can be reduced by degradation owing to exciton density.

Also, as illustrated in FIG. 6, when the single emitting material layer includes the P-type host PH and the second N-type host NH2 with relatively low LUMO energy level, exciplex between the HOMO energy level of the P-type host PH and the LUMO energy level of the second N-type host NH2 is formed. In this case, the formed exciplex is leaked outwardly of the emitting material layer and lost without emission so that the luminous efficiency such as EQE of the diode is lowered.

Referring to FIGS. 3 and 4, the difference ΔE1 between the LUMO energy level of the first N-type host 352 (NH1), and the HOMO energy level of the first P-type host 354 (PH1) and/or the second P-type host 364 (PH2) can be between about 2.3 eV and about 2.5 eV. Alternatively, the difference ΔE2 between the LUMO energy level of the second N-type host 362 (NH2), and the HOMO energy level of the first P-type host 354 (PH1) and/or the second P-type host 364 (PH2) can be between about 1.8 eV and about 2.2 eV.

As an example, each of the first P-type host 354 (PH1) and the second P-type host 364 (PH2) can independently have the HOMO energy level, but is not limited to, between about −5.0 eV and about −5.3 eV, for example, about −5.1 eV and about −5.3 eV. For example, each of the Compound PH1, Compound PH2, Compound PH3, Compound PH4 and Compound PH5 in Chemical Formula 2 each of which can be used as the first P-type host 354 (PH1) and/or the second P-type host 364 (PH2) can have the HOMO energy level of −5.16 eV, −5.19 eV, −5.12 eV, −5.22 eV and −5.25 eV, respectively.

The LUMO energy level of the second N-type host 362 (NH2) can be lower than the LUMO energy level of the first N-type host 352 (NH1) by about 0.2 eV to about 0.4 eV. The electron mobility of the second N-type host 362 (NH2) can be larger than the electron mobility of the first N-type host 352 (NH1) because the LUMO energy level of the second N-type host 362 (NH2) is relatively low compared to the LUMO energy level of the first N-type host 352 (NH1). Accordingly, electrons can be injected rapidly into the EML 340 from the ETL 380.

As an example, the first N-type host 352 (NH1) can have the LUMO energy level, but is not limited to, between about −2.7 eV and about −2.95 eV. for example, −2.7 eV and −2.9 eV. For example, the LUMO energy level of Compound NH1-1, Compound NH1-2, Compound NH1-3, Compound NH1-4 and Compound NH1-5 in Chemical Formula 4 each of which can be used as the first N-type host 352 (NH1) is −2.82 eV, −2.78 eV, −2.77 eV, −2.81 eV and −2.85 eV, respectively.

As an example, the second N-type host 362 (NH2) can have the LUMO energy level, but is not limited to, between about −3.0 eV and about −3.3 eV, for example, −3.0 eV and −3.2 eV. For example, the LUMO energy level of Compound NH2-1, Compound NH2-2, Compound NH2-3, Compound NH2-4 and Compound NH2-5 in Chemical Formula 6 each of which can be used as the second N-type host 362 (NH2) is −3.08 eV, −3.11 eV, −3.05 eV, −3.10 eV and −3.08 eV, respectively.

In one example embodiment, the contents of the host including the first N-type host 352 and the first P-type host 354 in the R-EML1 350 can be between about 50 wt % and about 99 wt %, for example, about 80 wt % and about 95 wt % or about 94 wt % and about 98 wt % and the contents of the first red dopant 356 in the R-EML1 350 can be between about 1 wt % and about 50 wt %, for example, about 5 wt % and about 20 wt % or about 2 wt % and about 6 wt %, but is not limited thereto. The contents of the first N-type host 352 can be larger than the contents of the first P-type host 354 in the R-EML1 350. For example, the first P-type host 354 and the first N-type host 352 in the R-EML1 350 can be admixed with, but is not limited to, a weight ratio of about 1:9 to about 4:6, for example, about 2:8 to about 4:6 or about 3:7 to about 4:6.

In another example embodiment, the contents of the host including the second N-type host 362 and the second P-type host 364 in the R-EML2 360 can be between about 50 wt % and about 99 wt %, for example, about 80 wt % and about 95 wt % or about 94 wt % and about 98 wt % and the contents of the second red dopant 366 in the R-EML2 360 can be between about 1 wt % and about 50 wt %, for example, about 5 wt % and about 20 wt % or about 2 wt % and about 6 wt %, but is not limited thereto. The contents of the second N-type host 362 can be larger than the contents of the second P-type host 364 in the R-EML2 360. For example, the second P-type host 364 and the second N-type host 362 in the R-EML2 360 can be admixed with, but is not limited to, a weight ratio of about 1:9 to about 4:6, for example, about 2:8 to about 4:6 or about 3:7 to about 4:6.

In another example embodiment, the R-EML1 350 can have a thickness equal to or thinner than a thickness of the R-EML2 360. As an example, the R-EML2 360 can have the thickness 2-4 times thicker than the thickness of the R-EML1 350. For example, the EML 340 including the R-EML1 350 and the R-EML2 360 can have a thickness, but is not limited to, about 100 Å to about 250 Å, for example, about 150 Å to about 200 Å.

Referring to FIG. 3, the HIL 310 is disposed between the first electrode 210 and the HTL 320 and can improve an interface property between the inorganic first electrode 210 and the organic HTL 320. In one example embodiment, the HIL 310 can include, but is not limited to, 4,4′,4″-Tris(3-methylphenylamino)triphenylamine (MTDATA), 4,4′,4″-Tris(N,N-diphenyl-amino)triphenylamine (NATA), 4,4′,4″-Tris(N-(naphthalene-1-yl)-N-phenyl-amino)triphenylamine (1T-NATA), 4,4′,4″-Tris(N-(naphthalene-2-yl)-N-phenyl-amino)triphenylamine (2T-NATA), Copper phthalocyanine (CuPc), Tris(4-carbazoyl-9-yl-phenyl)amine (TCTA), N,N′-Diphenyl-N,N′-bis(1-naphthyl)-1,1′-biphenyl-4,4″-diamine (NPB; NPD), N,N′-Bis{4-[bis(3-methylphenyl)amino]phenyl}-N,N′-diphenyl-4,4′-biphenyldiamine (DNTPD), 1,4,5,8,9,11-Hexaazatriphenylenehexacarbonitrile (Dipyrazino[2,3-f:2′3′-h]quinoxaline-2,3,6,7,10,11-hexacarbonitrile; HAT-CN), 2,3,5,6-tetrafluoro-7,7,8,8-tetracyanoquinodimethane (F4-TCNQ), 1,3,4,5,7,8-hexafluorotetracyanonaphthoquinodimethane (F6-TCNNQ), 1,3,5-tris[4-(diphenylamino)phenyl]benzene (TDAPB), poly(3,4-ethylenedioxythiophene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine, N,N′-diphenyl-N,N′-di[4-(N,N′-diphenyl-amino)phenyl]benzidine (NPNPB), MgF₂, CaF₂, the compound of following Chemical Formula 9 and/or combinations thereof.

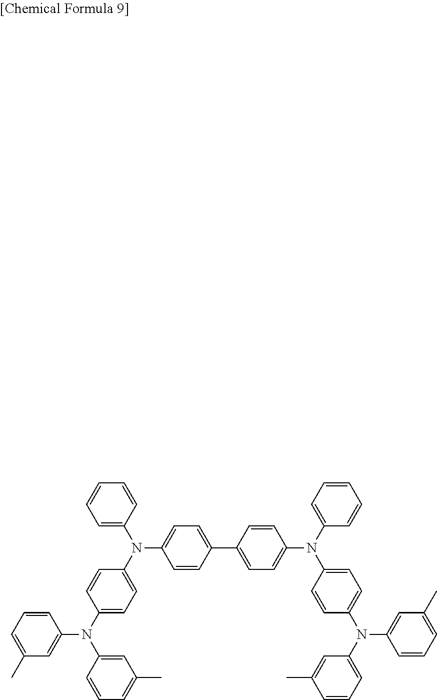 [SMILES: Cc1cccc(N(c2ccc(N(c3ccccc3)c3ccc(-c4ccc(N(c5ccccc5)c5ccc(N(c6cccc(C)c6)c6cccc(C)c6)cc5)cc4)cc3)cc2)c2cccc(C)c2)c1]

In an alternative embodiment, the HIL 310 can include a host of the above hole injecting material and/or hole transporting material below, and a P-type dopant. The P-type dopant can include, but is not limited to, HAT-CN, F4-TCNQ, F6-TCNNQ and/or combinations thereof. The contents of the P-type dopant in the HIL 310 can be, but is not limited to, about 1 wt % to about 10 wt %. As an example, the HIL 310 can have a thickness of, but is not limited to, about 1 to about 100 nm. The HIL 310 can be omitted in compliance of the OLED D1 property.

The HTL 320 is disposed between the first electrode 210 and the EML 340. In one example embodiment, the HTL 320 can include, but is not limited to, N,N′-Diphenyl-N,N′-bis(3-methylphenyl)-1,1′-biphenyl-4,4′-diamine (TPD), NPB(NPD), 4,4′-bis(N-carbazolyl)-1,1′-biphenyl (CBP), DNTPD, N4,N4,N4′,N4′-Tetra[(1,1′-biphenyl)-4-yl]-(1,1′-biphenyl)-4,4′-diamine (BPBPA), Poly[N,N′-bis(4-butylphenyl)-N,N′-bis(phenyl)-benzidine] (Poly-TPD), Poly[(9,9-dioctylfluorenyl-2,7-diyl)-co-(4,4′-(N-(4-sec-butylphenyl)diphenylamine))] (TFB), Di-[4-(N,N-di-p-tolyl-amino)-phenyl]cyclohexane (TAPC), 3,5-Di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine), N-([1,1′-Biphenyl]-4-yl)-9,9-dimethyl-N-(4-(9-phenyl-9H-carbazol -3-yl)phenyl)-9H-fluoren-2-amine, the organic compound having the structure of Chemical Formulae 1 to 2 and/or combinations thereof.

The ETL 380 and the EIL 390 can be laminated sequentially between the EML 340 and the second electrode 220. An electron transporting material included in the ETL 380 has high electron mobility so as to provide electrons stably with the EML 340 by fast electron transportation.

In one example embodiment, the ETL 380 can include at least one of an oxadiazole-based compound, a triazole-based compound, a phenanthroline-based compound, a benzoxazole-based compound, a benzothiazole-based compound, a benzimidazole-based compound, and a triazine-based compound.

For example, the ETL 380 can include, but is not limited to, tris-(8-hydroxyquinoline aluminum) (Alq₃), 2-biphenyl-4-yl-5-(4-t-butylphenyl)-1,3,4-oxadiazole (PBD), spiro-PBD, lithium quinolate (Liq), 2,2′,2″-(1,3,5-benzenetriyl)-tris(1-phenyl-1-H-benzimidazole) (TPBi), Bis(2-methyl-8-quinolinolato-N1,O8)-(1,1′-biphenyl-4-olato)aluminum (BAlq), 4,7-diphenyl-1,10-phenanthroline (Bphen), 2,9-Bis(naphthalene-2-yl)4,7-diphenyl-1,10-phenanthroline (NBphen), 2,9-Dimethyl-4,7-diphenyl-1,10-phenathroline (BCP), 3-(4-Biphenyl)-4-phenyl-5-tert-butylphenyl-1,2,4-triazole (TAZ), 4-(Naphthalen-1-yl)-3,5-diphenyl-4H-1,2,4-triazole (NTAZ), 3,5-Tri(p-pyrid-3-yl-phenyl)benzene (TpPyPB), 2,4,6-Tris(3′-(pyridin-3-yl)biphenyl-3-yl)1,3,5-triazine (TmPPPyTz), Poly[9,9-bis(3′-((N,N-dimethyl)-N-ethylammonium)-propyl)-2,7-fluorene]-alt-2,7-(9,9-dioctylfluorene)] (PFNBr), tris(phenylquinoxaline) (TPQ), TSPO1, 2-[4-(9,10-Di-2-naphthalen2-yl-2-anthracen-2-yl)phenyl]-1-phenyl-1H-benzimidazole (ZADN) and/or combinations thereof.

The EIL 390 is disposed between the second electrode 220 and the ETL 380, and can improve physical properties of the second electrode 220 and therefore, can enhance the lifespan of the OLED D1. In one example embodiment, the EIL 390 can include, but is not limited to, an alkali metal halide and/or an alkaline carth metal halide such as LiF, CsF, NaF, BaF₂ and the like, and/or an organometallic compound such as Liq, lithium benzoate, sodium stearate, and the like.

Alternatively, the ETL 380 and the EIL 390 can have a single layer where the electron transporting material and/or the electron injecting material are admixed. As an example, the electron transport/electron injection layer can have two different electron transporting materials. Two different electron transporting materials in the electron transport/electron injection layer can be admixed with, but is not limited to, a weight ratio of about 3:7 to about 7:3.

When holes are transferred to the second electrode 220 via the EML 340 and/or electrons are transferred to the first electrode 210 via the EML 340, the OLED D1 can have short lifespan and reduced luminous efficiency. In order to prevent those phenomena, the OLED D1 in accordance with this aspect of the present disclosure can have at least one exciton blocking layer adjacent to the EML 340.

As an example, the OLED D1 can include the EBL 330 between the HTL 320 and the EML 340 so as to control and prevent electron transfers. In one example embodiment, the EBL 330 can include, but is not limited to, TCTA, Tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, 1,3-Bis(carbazol-9-yl)benzene (mCP), 3,3-Di(9H-carbazol-9-yl)biphenyl (mCBP), CuPc, DNTPD, TDAPB, DCDPA, 2,8-bis(9-phenyl-9H-carbazol-3-yl)dibenzo[b,d]thiophene and/or combinations thereof.

In addition, the OLED D1 can further include the HBL 370 as a second exciton blocking layer between the EML 340 and the ETL 380 so that holes cannot be transferred from the EML 340 to the ETL 380. In one example embodiment, the HBL 370 can include, but is not limited to, at least one of an oxadiazole-based compound, a triazole-based compound, a phenanthroline-based compound, a benzoxazole-based compound, a benzothiazole-based compound, a benzimidazole-based compound, and a triazine-based compound.

For example, the HBL 370 can include material having a relatively low HOMO energy level compared to the luminescent materials in EML 340. The HBL 370 can include, but is not limited to, BCP, BAlq, Alq₃, PBD, spiro-PBD, Liq, Bis-4,5-(3,5-di-3-pyridylphenyl)-2-methylpyrimidine (B3PYMPM), Bis[2-(diphenylphosphino)phenyl]ether oxide (DPEPO), 9-(6-(9H-carbazol-9-yl)pyridine-3-yl)-9H-3,9′-bicarbazole, TSPO1 and/or combinations thereof. The EBL 330 and/or the HBL 370 can be omitted.

The R-EML1 350 disposed adjacently to the HTL 320 includes the first N-type host with relatively high (shallow) LUMO energy level so that no exciplex between the HTL 320 and the R-EML1 350 can be formed. On the other hand, the R-EML2 360 disposed adjacently to the ETL 380 includes the second N-type host with relatively low (deep) LUMO energy level so that exciplex between the HTL 320 and the R-EML2 360 can be formed. The OLED D1 having improved luminous properties can be realized by minimizing exciton loss and inducing the exciton formation within the EML 340.

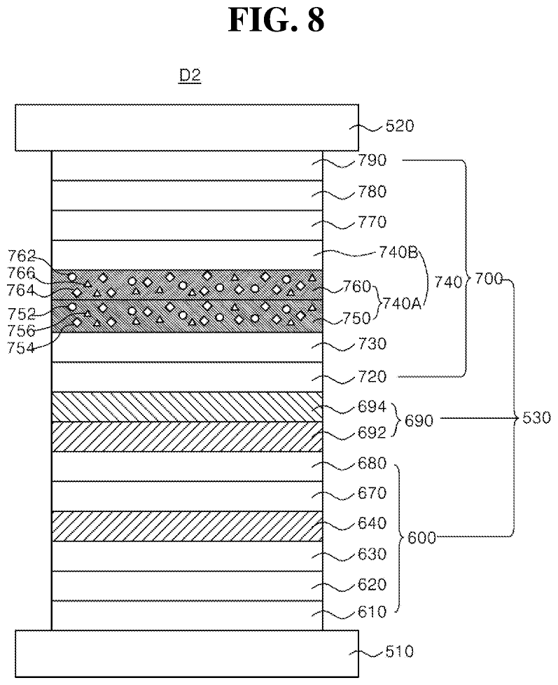

In another example embodiment, an organic light emitting display device can implement full-color including white color. FIG. 7 illustrates a schematic cross-sectional view of an organic light emitting display device in accordance with another example embodiment of the present disclosure.

As illustrated in FIG. 7, the organic light emitting display device 400 comprises a first substrate 402 that defines each of a red pixel region RP, a green pixel region GP and a blue pixel region BP, a second substrate 404 facing the first substrate 402, a thin film transistor Tr on the first substrate 402, an OLED D disposed between the first and second substrates 402 and 404 and emitting white (W) light and a color filter layer 480 disposed between the OLED D and the second substrate 404.

Each of the first and second substrates 402 and 404 can include, but is not limited to, glass, flexible material and/or polymer plastics. For example, each of the first and second substrates 402 and 404 can be made of PI, PES, PEN, PET, PC and/or combinations thereof. The first substrate 402, on which a thin film transistor Tr and the OLED D are arranged, forms an array substrate. The second substrate 404 can be omitted.

A buffer layer 406 can be disposed on the first substrate 402. The thin film transistor Tr is disposed on the buffer layer 406 correspondingly to each of the red pixel region RP, the green pixel region GP and the blue pixel region BP. The buffer layer 406 can be omitted.

A semiconductor layer 410 is disposed on the buffer layer 406. The semiconductor layer 410 can be made of or include oxide semiconductor material or polycrystalline silicon.

A gate insulating layer 420 including an insulating material, for example, inorganic insulating material such as silicon oxide (SiOₓ, wherein 0<x≤2) or silicon nitride (SiNₓ, wherein 0<x≤2) is disposed on the semiconductor layer 410.

A gate electrode 430 made of a conductive material such as a metal is disposed over the gate insulating layer 420 so as to correspond to a center of the semiconductor layer 410. An interlayer insulating layer 440 including an insulating material, for example, inorganic insulating material such as SiOₓ or SiNₓ, or an organic insulating material such as benzocyclobutene or photo-acryl, is disposed on the gate electrode 430.

The interlayer insulating layer 440 has first and second semiconductor layer contact holes 442 and 444 that expose or do not cover a portion of the surface nearer to the opposing ends than to a center of the semiconductor layer 410. The first and second semiconductor layer contact holes 442 and 444 are disposed on opposite sides of the gate electrode 430 with spacing apart from the gate electrode 430.

A source electrode 452 and a drain electrode 454, which are made of or include a conductive material such as a metal, are disposed on the interlayer insulating layer 440. The source electrode 452 and the drain electrode 454 are spaced apart from each other with respect to the gate electrode 430. The source electrode 452 and the drain electrode 454 contact both sides of the semiconductor layer 410 through the first and second semiconductor layer contact holes 442 and 444, respectively.

The semiconductor layer 410, the gate electrode 430, the source electrode 452 and the drain electrode 454 constitute the thin film transistor Tr, which acts as a driving element.

Although not shown in FIG. 7, the gate line GL and the data line DL, which cross cach other to define the pixel region P, and a switching element Ts, which is connected to the gate line GL and the data line DL, can be further formed in the pixel region P. The switching element Ts is connected to the thin film transistor Tr, which is a driving element. In addition, the power line PL is spaced apart in parallel from the gate line GL or the data line DL, and the thin film transistor Tr can further include the storage capacitor Cst configured to constantly keep a voltage of the gate electrode 430 for one frame.

A passivation layer 460 is disposed on the source electrode 452 and the drain electrode 454 and covers the thin film transistor Tr over the whole first substrate 402. The passivation layer 460 has a drain contact hole 462 that exposes or does not cover the drain electrode 454 of the thin film transistor Tr.

The OLED D is located on the passivation layer 460. The OLED D includes a first electrode 510 that is connected to the drain electrode 454 of the thin film transistor Tr, a second electrode 520 facing the first electrode 510 and an emissive layer 530 disposed between the first and second electrodes 510 and 520.

The first electrode 510 formed for each pixel region RP, GP or BP can be an anode and can include a conductive material having relatively high work function value. For example, the first electrode 510 can include, but is not limited to, ITO, IZO, ITZO, SnO, ZnO, ICO, AZO, and/or combinations thereof. Alternatively, a reflective electrode or a reflective layer can be disposed under the first electrode 510. For example, the reflective electrode or the reflective layer can include, but is not limited to, Ag or APC alloy.

A bank layer 464 is disposed on the passivation layer 460 in order to cover edges of the first electrode 510. The bank layer 464 exposes or does not cover a center of the first electrode 510 corresponding to each of the red pixel region RP, the green pixel region GP and the blue pixel region BP. The bank layer 464 can be omitted.

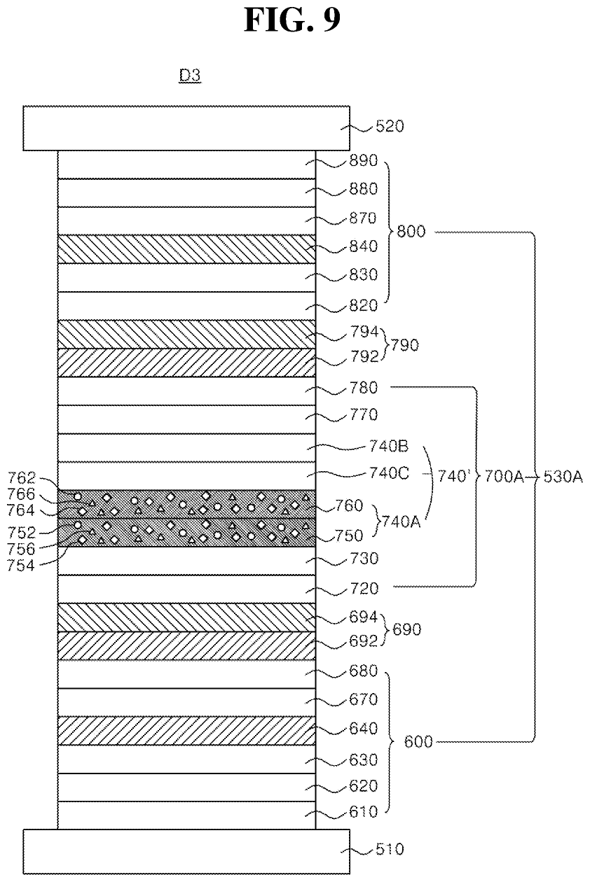

An emissive layer 530 that can include multiple emitting parts is disposed on the first electrode 510. As illustrated in FIGS. 8 to 10, the emissive layer 530 can include multiple emitting parts 600, 600A, 700, 700A, 700B, 800, 800A and 900, and at least one charge generation layer 690, 790 and 890. Each of the emitting parts 600, 600A, 700, 700A, 700B, 800, 800A and 900 can include at least one emitting material layer and can further include an HIL, an HTL, an EBL, an HBL, an ETL and/or an EIL.

The second electrode 520 can be disposed on the first substrate 402 above which the emissive layer 530 can be disposed. The second electrode 520 can be disposed over a whole display area, can include a conductive material with a relatively low work function value compared to the first electrode 510, and can be a cathode. For example, the second electrode 520 can include, but is not limited to, highly reflective material such as Al, Mg, Ca, Ag, alloy thereof, and/or combinations thereof such as Al—Mg.

Since the light emitted from the emissive layer 530 is incident to the color filter layer 480 through the second electrode 520 in the organic light emitting display device 400 in accordance with the second embodiment of the present disclosure, the second electrode 520 has a thin thickness so that the light can be transmitted.

The color filter layer 480 is disposed on the OLED D and includes a red color filter pattern 482, a green color filter pattern 484 and a blue color filter pattern 486 each of which is disposed correspondingly to the red pixel region RP, the green pixel region GP and the blue pixel region BP, respectively. Although not shown in FIG. 7, the color filter layer 480 can be attached to the OLED D through an adhesive layer. Alternatively, the color filter layer 480 can be disposed directly on the OLED D.

In addition, an encapsulation film 470 can be disposed on the second electrode 520 in order to prevent or reduce outer moisture from penetrating into the OLED D. The encapsulation film 470 can have, but is not limited to, a laminated structure including a first inorganic insulating film, an organic insulating film and a second inorganic insulating film (170 in FIG. 2). In addition, a polarizing plate can be attached onto the second substrate 404 to reduce reflection of external light. For example, the polarizing plate can be a circular polarizing plate.

In FIG. 7, the light emitted from the OLED D is transmitted through the second electrode 520 and the color filter layer 480 is disposed on the OLED D. Alternatively, when the organic light emitting display device 400 is a bottom-emission type, the light emitted from the OLED D is transmitted through the first electrode 510 and the color filter layer can be disposed between the first substrate 402 and the OLED D.

In addition, a color conversion layer may be formed or disposed between the OLED D and the color filter layer 480. The color conversion layer may include a red color conversion layer, a green color conversion layer and a blue color conversion layer each of which is disposed correspondingly to each pixel region (RP, GP and BP), respectively, so as to convert the white (W) color light to each of a red, green and blue color lights, respectively. Alternatively, the organic light emitting display device 400 can comprise the color conversion layer instead of the color filter layer 480.

As described above, the white (W) color light emitted from the OLED D is transmitted through the red color filter pattern 482, the green color filter pattern 484 and the blue color filter pattern 486 cach of which is disposed correspondingly to the red pixel region RP, the green pixel region GP and the blue pixel region BP, respectively, so that red, green and blue color lights are displayed in the red pixel region RP, the green pixel region GP and the blue pixel region BP.

An OLED that can be applied into the organic light emitting display device will be described in more detail. FIG. 8 illustrates a schematic cross-sectional view of an organic light emitting diode having a tandem structure of two emitting parts. As illustrated in FIG. 8, the OLED D2 in accordance with the example embodiment of the present disclosure includes first and second electrodes 510 and 520 and an emissive layer 530 disposed between the first and second electrodes 510 and 520. The emissive layer 530 includes a first emitting part 600 disposed between the first electrode 510 and the second electrode 520, a second emitting part 700 disposed between the first emitting part 600 and the second electrode 520 and a charge generation layer (CGL) 690 disposed between the first emitting part 600 and the second emitting part 700.

The first electrode 510 can be an anode and can include a conductive material having relatively high work function value such as TCO. For example, the first electrode 510 can include, but is not limited to, ITO, IZO, ITZO, SnO, ZnO, ICO, AZO, and/or combinations thereof. The second electrode 520 can be a cathode and can include a conductive material with a relatively low work function value. For example, the second electrode 520 can include, but is not limited to, highly reflective material such as Al, Mg, Ca, Ag, alloy thereof and/or combination thereof such as Al—Mg.

The first emitting part 600 includes a first emitting material layer (EML1) 640. The first emitting part 600 can include at least one of a hole injection layer (HIL) 610 disposed between the first electrode 510 and the EML1 640, a first hole transport layer (HTL1) 620 disposed between the HIL 610 and the EML1 640 and a first electron transport layer (ETL1) 680 disposed between the EML1 640 and the CGL 690. Alternatively, the first emitting part 600 can further include a first electron blocking layer (EBL1) 630 disposed between the HTL1 620 and the EML1 640 and/or a first hole blocking layer (HBL1) 670 disposed between the EML1 640 and the ETL1 680.

The second emitting part 700 includes a second emitting material layer (EML2) 740. The second emitting part 700 can include at least one of a second hole transport layer (HTL2) 720 disposed between the CGL 690 and the EML2 740, a second electron transport layer (ETL2) 780 disposed between the EML2 740 and the second electrode 520 and an electron injection layer (EIL) 790 disposed between the ETL2 780 and the second electrode 520. Alternatively, the second emitting part 700 can further include a second electron blocking layer (EBL2) 730 disposed between the HTL2 720 and the EML2 740 and/or a second hole blocking layer (HBL2) 770 disposed between the EML2 740 and the ETL2 780.

At least one of the EML1 640 and the EML2 740 can emit red to green color light. Alternatively, one of the EML1 640 and the EML2 740 can emit red to green color light and the other of the EML1 640 and the EML2 740 can emit blue color light so that the OLED D2 can implement white color (W) emission. Hereinafter, the OLED D2 where the EML2 740 emits red to green color light will be described in detail.

The HIL 610 is disposed between the first electrode 510 and the HTL1 620 and improves an interface property between the inorganic first electrode 510 and the organic HTL1 620. In one exemplary embodiment, the HIL 610 can include, but is not limited to, MTDATA, NATA, IT-NATA, 2T-NATA, CuPc, TCTA, NPB (NPD), DNTPD, HAT-CN, TDAPB, PEDOT/PSS, N-(biphenyl-4-yl)-9,9-dimethyl-N-(4-(9-phenyl-9H-carbazol-3-yl)phenyl)-9H-fluoren-2-amine, NPNPB, MgF₂, CaF₂, the compound of Chemical Formula 9 and/or combinations thereof. Alternatively, the HIL 610 can include a host of the hole injecting material and/or the hole transporting material and a P-type dopant that can be HAT-CN, F4-TCNQ, F6-TCNNQ and/or combinations thereof. The HIL 610 can be omitted in compliance of the OLED D2 property.

In one example embodiment, each of the HTL1 620 and the HTL2 720 can include, but is not limited to, TPD, NPB (NPD), DNTPD, BPBPA, CBP, Poly-TPD, TFB, TAPC, DCDPA, N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine, N-([1,1′-Biphenyl]-4-yl)-9,9-dimethyl-N-(4-(9-phenyl-9H-carbazol-3-yl)phenyl)-9H-fluoren-2-amine and/or combination thereof.

Each of the ETL1 680 and the ETL2 780 transports electrons to each of the EML1 640 and the EML2 740, respectively. As an example, each of the ETL1 680 and the ETL2 780 can include at least one of an oxadiazole-based compound, a triazole-based compound, a phenanthroline-based compound, a benzoxazole-based compound, a benzothiazole-based compound, a benzimidazole-based compound and a triazine-based compound. For example, each of the ETL1 680 and the ETL2 780 can include, but is not limited to, Alq₃, PBD, spiro-PBD, Liq, TPBi, BAlq, Bphen, NBphen, BCP, TAZ, NTAZ, TpPyPB, TmPPPyTz, PFNBr, TPQ, TSPO1, ZADN and/or combinations thereof.

The EIL 790 is disposed between the second electrode 520 and the ETL2 780, and can improve physical properties of the second electrode 520 and therefore, can enhance the lifespan of the OLED D2. In one example embodiment, the EIL 790 can include, but is not limited to, an alkali metal halide or an alkaline carth metal halide such as LiF, CsF, NaF, BaF₂ and the like, and/or an organometallic Compound such as Liq, lithium benzoate, sodium stearate, and the like.

Each of the EBL1 630 and the EBL2 730 can independently include, but is not limited to, TCTA, Tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, mCP, mCBP, CuPc, DNTPD, TDAPB, DCDPA, 2,8-bis(9-phenyl-9H-carbazol-3-yl)dibenzo[b,d]thiophene and/or combinations thereof, respectively.

Each of the HBL1 670 and the HBL2 770 can include, but is not limited to, at least one of an oxadiazole-based compound, a triazole-based compound, a phenanthroline-based compound, a benzoxazole-based compound, a benzothiazole-based compound, a benzimidazole-based compound, and a triazine-based compound. For example, each of the HBL1 670 and the HBL2 770 can independently include, but is not limited to, BCP, BAlq, Alq₃, PBD, spiro-PBD, Liq, B3PYMPM, DPEPO, 9-(6-(9H-carbazol-9-yl)pyridine-3-yl)-9H-3,9′-bicarbazole, TSPO1 and/or combinations thereof, respectively.

The CGL 690 is disposed between the first emitting part 600 and the second emitting part 700. The CGL 690 includes an N-type charge generation layer (N-CGL) 692 disposed adjacently to the first emitting part 600 and a P-type charge generation layer (P-CGL) 694 disposed adjacently to the second emitting part 700. The N-CGL 692 injects electrons to the EML1 640 of the first emitting part 600 and the P-CGL 694 injects holes to the EML2 740 of the second emitting part 700.

The N-CGL 692 can be an organic layer doped with an alkali metal such as Li, Na, K and Cs and/or an alkaline carth metal such as Mg, Sr, Ba and Ra. For example, the host in each of the N-CGL 692 can include, but is not limited to, Bphen and MTDATA. The contents of the alkali metal or the alkaline earth metal in the N-CGL 692 can be between about 0.01 wt % and about 30 wt %.

The P-CGL 694 can include, but is not limited to, inorganic material selected from the group consisting of WOₓ, MoOₓ, Be₂O₃, V₂O₅ and combinations thereof and/or organic material selected from the group consisting of NPD, DNTPD, HAT-CN, F4-TCNQ, F6-TCNNQ, TPD, N,N,N′,N′-tetranaphthalenyl-benzidine (TNB), TCTA, N,N′-dioctyl-3,4,9,10-perylenedicarboximide (PTCDI-C8) and/or combinations thereof.

The EML1 640 can be a blue emitting material layer. In this case, the EML1 640 can be a blue EML, a sky-blue EML or a deep-blue EML. The EML1 640 can include a blue host of one or more and a blue dopant (blue emitter).

For example, the blue host can include, but is not limited to, mCP, 9-(3-(9H-carbazol-9-yl)phenyl)-9H-carbazole-3-carbonitrile (mCP-CN), mCBP, CBP-CN, 9-(3-(9H-Carbazol-9-yl)phenyl)-3-(diphenylphosphoryl)-9H-carbazole (mCPPO1) 3,5-Di(9H-carbazol-9-yl)biphenyl (Ph-mCP), TSPO1, 9-(3′-(9H-carbazol-9-yl)-[1,1′-biphenyl]-3-yl)-9H-pyrido[2,3-b]indole (CzBPCb), Bis(2-methylphenyl)diphenylsilane (UGH-1), 1,4-Bis(triphenylsilyl)benzene (UGH-2), 1,3-Bis(triphenylsilyl)benzene (UGH-3), 9,9-Spiorobifluoren-2-yl-diphenyl-phosphine oxide (SPPO1), 9,9′-(5-(Triphenylsilyl)-1,3-phenylene)bis(9H-carbazole) (SimCP) and/or combinations thercof.

The blue dopant can include at least one of blue phosphorescent material, blue fluorescent material and blue delayed fluorescent material. For example, the blue dopant can include, but is not limited to, perylene, 4,4′-Bis[4-(di-p-tolylamino)styryl]biphenyl (DPAVBi), 4-(Di-p-tolylamino)-4-4′-[(di-p-tolylamino)styryl]stilbene (DPAVB), 4,4′-Bis[4-(diphenylamino)styryl]biphenyl (BDAVBi), 2,7-Bis(4-diphenylamino)styryl)-9,9-spirofluorene (spiro-DPVBi), [1,4-bis[2-[4-[N,N-di(p-tolyl)amino]phenyl]vinyl]benzene (DSB), 1-4-di-[4-(N,N-diphenyl)amino]styryl-benzene (DSA), 2,5,8,11-Tetra-tetr-butylperylene (TBPe), Bis(2-hydroxylphenyl)-pyridine)beryllium (Bepp₂), 9-(9-Phenylcarbazol-3-yl)-10-(naphthalen-1-yl)anthracene (PCAN), mer-Tris(1-phenyl-3-methylimidazolin-2-ylidene-C,C(2)′iridium(III) (mer-Ir(pmi)₃), fac-Tris(1,3-diphenyl-benzimidazolin-2-ylidene-C,C(2)′iridium(III) (fac-Ir(dpbic)₃), Bis(3,4,5-trifluoro-2-(2-pyridyl)phenyl-(2-carboxypyridyl)iridium(III) ((Ir(tfpd)₂pic), tris(2-(4,6-difluorophenyl)pyridine))iridium(III) ((Ir(Fppy)₃), Bis[2-(4,6-difluorophenyl)pyridinato-C²,N](picolinato)iridium(III) (FIrpic), DABNA-1, DABNA-2, t-DABNA, v-DABNA and/or combinations thereof.

When the EML1 640 includes the blue host of one or more, the contents of the host in the EML1 640 can be about 50 wt % to about 99 wt %, for example, about 80 wt % to about 95 wt %, and the contents of the blue dopant in the EML1 640 can be about 1 wt % to about 50 wt %, for example, about 5 wt % to about 20 wt %, but is not limited thereto. When the EML1 640 includes a P-type blue host and an N-type blue host, the P-type blue host and the N-type blue host in the EML1 640 can be admixed, but is not limited to, with a weight ratio of about 4:1 to about 1:4, for example about 3:1 to about 1:3.

The EML2 740 can include a first layer (lower emitting material layer) 740A disposed between the EBL2 730 and the HBL2 770 and a second layer (upper emitting material layer) 740B disposed between the first layer 740A and the HBL2 770. One of the first layer 740A and the second layer 740B can emit red color light and the other of the first layer 740A and the second layer 740B can emit green color light. Hereinafter, the EML2 740 where the first layer 740A emits red color light and the second layer 740B emits green color light will be described in detail.

The first layer 740A includes a first red emitting material layer (R-EML1) 750 and a second red emitting material layer (R-EML2) 760 disposed between the R-EML1 750 and the second layer 740B. The R-EML1 750 includes a first N-type host 752, and optionally, a first P-type host 754 and/or a first red dopant (first red emitter) 756. The R-EML2 760 includes a second N-type host 762, and optionally, a second P-type host 764 and/or a second red dopant (second red emitter) 766. The structure, energy level and contents of the first N-type host 752, the first P-type host 754, the first red dopant 756, the second N-type host 762, the second P-type host 764 and the second red dopant 766 can be identical to corresponding materials with referring to FIGS. 3 to 4.

The second layer 740B includes a green host of one or more and a green dopant (green emitter). The green host can be the blue host above. Alternatively, the green host can include, but is not limited to, a P-type green host of a biscarbzole-based organic compound, an aryl amine- or a hetero aryl amine-based organic compound having at least one fused aromatic and/or hetero aromatic moiety, and/or an aryl amine- or a hetero aryl amine-based organic compound having at least one spirofluorene moiety and/or an N-type green host of an azine-based organic compound.

As an example, the green host can include, but is not limited to, mCP-CN, CBP, mCBP, mCP, DPEPO, 2,8-bis(diphenylphosphoryl)dibenzothiophene (PPT), 1,3,5-Tri[(3-pyridyl)-phen-3-yl]benzene (TmPyPB), 2,6-Di(9H-carbazol-9-yl)pyridine (PYD-2Cz), 2,8-di(9H-carbazol-9-yl)dibenzothiophene (DCzDBT), 3′,5′-Di(carbazol-9-yl)-[1,1′-bipheyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, 9,9′-Diphenyl-9H,9′H-3,3′-bicarbazole (BCzPh), 1,3,5-Tris(carbazole-9-yl)benzene (TCP), TCTA, 4,4′-Bis(carbazole-9-yl)-2,2′-dimethylbipheyl (CDBP), 2,7-Bis(carbazole-9-yl)-9,9-dimethylfluorene (DMFL-CBP), 2,2′,7,7′-Tetrakis(carbazole-9-yl)-9,9-spirofluorene (Spiro-CBP), 3,6-Bis(carbazole-9-yl)-9-(2-ethyl-hexyl)-9H-carbazole (TCz1) and/or combinations thereof.

The green dopant can include at least one of green phosphorescent material, green fluorescent material and green delayed fluorescent material. As an example, the green dopant can include, but is not limited to, [Bis(2-phenylpyridine)](pyridyl-2-benzofuro[2,3-b]pyridine)iridium, Tris[2-phenylpyridine]iridium(III) (Ir(ppy)₃), fac-Tris(2-phenylpyridine)iridium(III) (fac-Ir(ppy)₃), Bis(2-phenylpyridine)(acetylacetonate)iridium(III) (Ir(ppy)₂(acac)), Tris[2-(p-tolyl)pyridine]iridium(III) (Ir(mppy)₃), Bis(2-(naphthalene-2-yl)pyridine)(acetylacetonate)iridium(III) (Ir(npy)₂acac), Tris(2-phenyl-3-methyl-pyridine)iridium (Ir(3mppy)₃), fac-Tris(2-(3-p-xylyl)phenyl)pyridine iridium (III) (TEG), the compound of the following Chemical Formula 10 and/or combinations thereof.

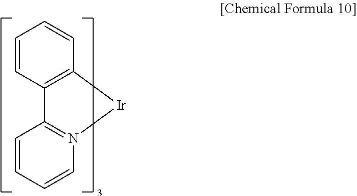

For example, the contents of the green host in the second layer 740B can be about 50 wt % to about 99 wt %, for example, about 80 wt % to about 95 wt %, and the contents of the green dopant in the second layer 740B can be about 1 wt % to about 50 wt %, for example, about 5 wt % to about 20 wt %, but is not limited thereto. When the second layer 740B includes a P-type green host and an N-type green host, the P-type green host and the N-type green host in the second layer 740B can be admixed, but is not limited to, with a weight ratio of about 4:1 to about 1:4, for example about 3:1 to about 1:3. As an example, the second layer 740B can have a thickness, but is not limited to, about 300 Å to about 400 Å.

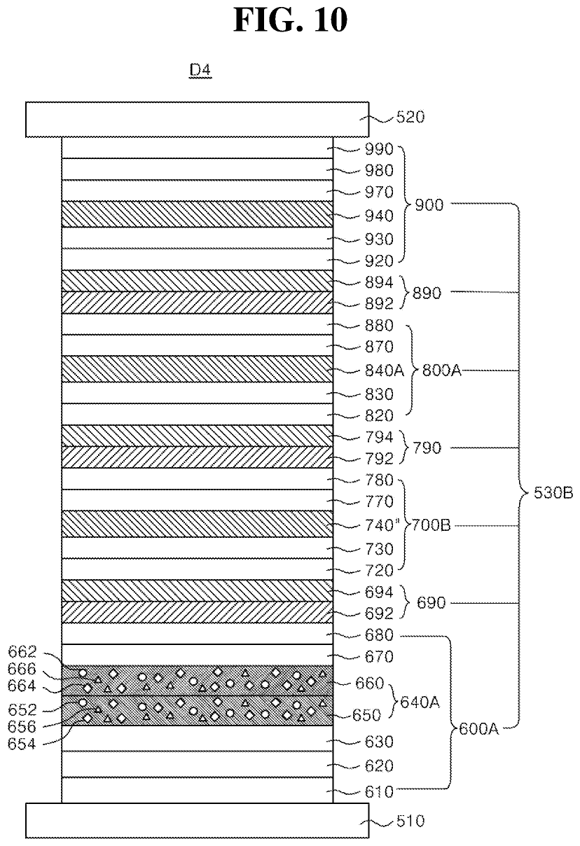

Alternatively, the EML2 740 can further include a third layer 740C (FIG. 9) of a yellow-green emitting material layer disposed between the first layer 740A of the red emitting material layer and the second layer 740B of the green emitting material layer.

An organic light emitting diode can have a tandem structure of three or more emitting parts. FIG. 9 illustrates a cross-sectional view of an organic light emitting diode having a tandem structure of three emitting parts in accordance with another example embodiment of the present disclosure.

As illustrated in FIG. 9, the organic light emitting diode (OLED) D3 in accordance with another example embodiment of the present disclosure includes a first electrode 510, a second electrode 520 facing the first electrode 510 and an emissive layer 530A disposed between the first electrode 510 and the second electrode 520. The emissive layer 530A includes a first emitting part 600 disposed between the first electrode 510 and the second electrode 520, a second emitting part 700A disposed between the first emitting part 600 and the second electrode 520, a third emitting part 800 disposed between the second emitting part 700A and the second electrode 520, a first charge generation layer (CGL1) 690 disposed between the first emitting part 600 and the second emitting part 700A and a second charge generation layer (CGL2) 790 disposed between the second emitting part 700A and the third emitting part 800.

The first emitting part 600 includes a first emitting material layer (EML1) 640. The first emitting part 600 can include at least one of a hole injection layer (HIL) 610 disposed between the first electrode 510 and the EML1 640, a first hole transport layer (HTL1) 620 disposed between the HIL 610 and the EML1 640 and a first electron transport layer (ETL1) 680 disposed between the EML1 640 and the CGL1 690. Alternatively, the first emitting part 600 can further include a first electron blocking layer (EBL1) 630 disposed between the HTL1 620 and the EML1 640 and/or a first hole blocking layer (HBL1) 670 disposed between the EML1 640 and the ETL1 680.

The second emitting part 700A includes a second emitting material layer (EML2) 740′. The second emitting part 700A can include at least one of a second hole transport layer (HTL2) 720 disposed between the CGL1 690 and the EML2 740′ and a second electron transport layer (ETL2) 780 disposed between the EML2 740′ and the CGL2 790. Alternatively, the second emitting part 700A can further include a second electron blocking layer (EBL2) 730 disposed between the HTL2 720 and the EML2 740′ and/or a second hole blocking layer (HBL2) 770 disposed between the EML2 740′ and the ETL2 780.

The second emitting part 800 includes a third emitting material layer (EML3) 840. The third emitting part 800 can include at least one of a third hole transport layer (HTL3) 820 disposed between the CGL2 790 and the EML3 840, a third electron transport layer (ETL3) 880 disposed between the EML3 840 and the second electrode 520 and an electron injection layer (EIL) 890 disposed between the ETL3 880 and the second electrode 520. Alternatively, the third emitting part 800 can further include a third electron blocking layer (EBL3) 830 disposed between the HTL3 820 and the EML3 840 and/or a third hole blocking layer (HBL3) 870 disposed between the EML3 840 and the ETL3 880.

The CGL1 690 is disposed between the first emitting part 600 and the second emitting part 700A and the CGL2 790 is disposed between the second emitting part 700A and the third emitting part 800. The CGL1 690 includes a first N-type charge generation layer (N-CGL1) 692 disposed adjacently to the first emitting part 600 and a first P-type charge generation layer (P-CGL1) 694 disposed adjacently to the second emitting part 700A. The CGL2 790 includes a second N-type charge generation layer (N-CGL2) 792 disposed adjacently to the second emitting part 700A and a second P-type charge generation layer (P-CGL2) 794 disposed adjacently to the third emitting part 800.

Each of the N-CGL1 692 and the N-CGL2 792 injects electrons to the EML1 640 of the first emitting part 600 and the EML2 740′ of the second emitting part 700A, respectively, and each of the P-CGL1 694 and the P-CGL2 794 injects holes to the EML2 740′ of the second emitting part 700A and the EML3 840 of the third emitting part 800, respectively.

The materials of the HIL 610, the first to third HTLs 620, 720, and 820, the first to third EBLs 630, 730 and 830, the first to third HBLs 670, 770, and 870, the first to third ETLs 680, 780 and 880, the EIL 890 and the first to second CGLs 690 and 790 can be identical to corresponding materials with referring to FIGS. 3 and 8.

In the OLED D3, at least one of the first to third emitting parts 600, 700A, and 800 can emit red to green color light and the other of the first to third emitting parts 600, 700A, and 800 can emit blue color light, so that the OLED D3 can implement white emission. Hereinafter, the OLED D3 where the second emitting part 700A emits red to green color light and the first emitting part 600 and the third emitting part 800 emits blue color light will be described in detail.

When the EML1 640 and the EML3 840 is the blue emitting material layer, each of the EML1 640 and the EML3 840 can be independently be a blue emitting material layer, a sky-blue emitting material layer or a deep-blue emitting material layer. Each of the EML1 640 and the EML3 840 can independently include a blue host of one or more and a blue dopant (blue emitter). The blue host and the blue dopant can be identical to corresponding materials with referring to FIG. 8. For example, the blue dopant can include at least one of blue phosphorescent material, blue fluorescent material and blue delayed fluorescent material. Alternatively, the blue host and/or the blue dopant in the EML1 640 can be different from the blue host and/or the blue dopant in the EML3 840 in terms of emission wavelength and/or luminous efficiency.

When the EML1 640 and/or the EML3 840 include the blue host of one or more, the contents of the host in the EML1 640 and/or the EML3 840 can be about 50 wt % to about 99 wt %, for example, about 80 wt % to about 95 wt %, and the contents of the blue dopant in the EML1 640 and/or the EML3 840 can be about 1 wt % to about 50 wt %, for example, about 5 wt % to about 20 wt %, but is not limited thereto. When the EML1 640 and/or the EML3 840 include a P-type blue host and an N-type blue host, the P-type blue host and the N-type blue host in the EML1 640 and/or the EML3 840 can be admixed, but is not limited to, with a weight ratio of about 4:1 to about 1:4, for example about 3:1 to about 1:3.

The EML2 740′ includes a first layer (lower emitting material layer) 740A disposed between the EBL2 730 and the HBL2 770, a second layer (upper emitting material layer) 740B disposed between the first layer 740A and the HBL2 770 and a third layer (middle emitting material layer) 740C disposed between the first layer 740A and the second layer 740B. One of the first layer 740A and the second layer 740B can emit red color light and the other of the first layer 740A and the second layer 740B can emit green color light. Hereinafter, the EML2 740′ where the first layer 740A emits red color light and the second layer 740B emits green color light will be described in detail.

The first layer 740A includes a first red emitting material layer (R-EML1) 750 and a second red emitting material layer (R-EML2) 760 disposed between the R-EML1 750 and the third layer 740C. The R-EML1 750 includes a first N-type host 752, and optionally, a first P-type host 754 and/or a first red dopant (first red emitter) 756. The R-EML2 760 includes a second N-type host 762, and optionally, a second P-type host 764 and/or a second red dopant (second red emitter) 766. The structure, energy level and contents of the first N-type host 752, the first P-type host 754, the first red dopant 756, the second N-type host 762, the second P-type host 764 and the second red dopant 766 can be identical to corresponding materials with referring to FIGS. 3, 4 and 8.

The second layer 740B includes a green host of one or more and a green dopant (green emitter). The structure and/or the contents of the green host and the green dopant can be identical to the corresponding materials with referring to FIG. 8.

The third layer 740C can be a yellow-green emitting material layer. The third layer 740C can include a yellow-green host of one or more and a yellow-green dopant (yellow-green emitter). As an example, the yellow-green host can be identical to the green host and/or the red host above. The yellow-green dopant can include at least one of yellow-green phosphorescent material, yellow-green fluorescent material and yellow-green delayed fluorescent material.

For example, the yellow-green dopant can include, but is not limited to, 5,6,11,12-Tetraphenylnaphthalene (Rubrene), 2,8-Di-tert-butyl-5,11-bis(4-tert-butylphenyl)-6,12-diphenyltetracene (TBRb), Bis(2-phenylbenzothiazolato)(acetylacetonate)iridium(III) (Ir(BT)₂(acac)), Bis(2-(9,9-dicthytl-fluoren-2-yl)-1-phenyl-1H-benzo[d]imdiazolato)(acetylacetonate)iridium(III) (Ir(fbi)₂(acac)), Bis(2-phenylpyridine)(3-(pyridine-2-yl)-2H-chromen-2-onate)iridium(III) (fac-Ir(ppy)₂Pc), Bis(2-(2,4-difluorophenyl)quinoline)(picolinate)iridium(III) (FPQIrpic), Bis(4-phenylthieno[3,2-c]pyridinato-N,C2′) (acetylacetonate)iridium(III) (PO-01), the compound of the following Chemical Formula 11 and/or combinations thereof. The third layer 740C can be omitted.

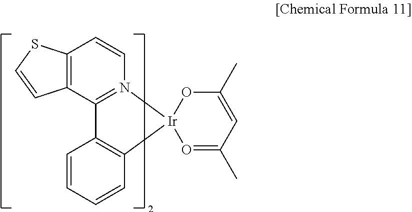

When the third layer 740C includes the yellow-green host of one or more, the contents of the yellow-green host in the third layer 740C can be about 50 wt % to about 99 wt %, for example, about 80 wt % to about 95 wt %, and the contents of the yellow-green dopant in the third layer 740C can be about 1 wt % to about 50 wt %, for example, about 5 wt % to about 20 wt %, but is not limited thereto. When the third layer 740C includes a P-type yellow-green host and an N-type yellow-green host, the P-type yellow-green host and the N-type yellow-green host in third layer 740C can be admixed, but is not limited to, with a weight ratio of about 4:1 to about 1:4, for example about 3:1 to about 1:3.

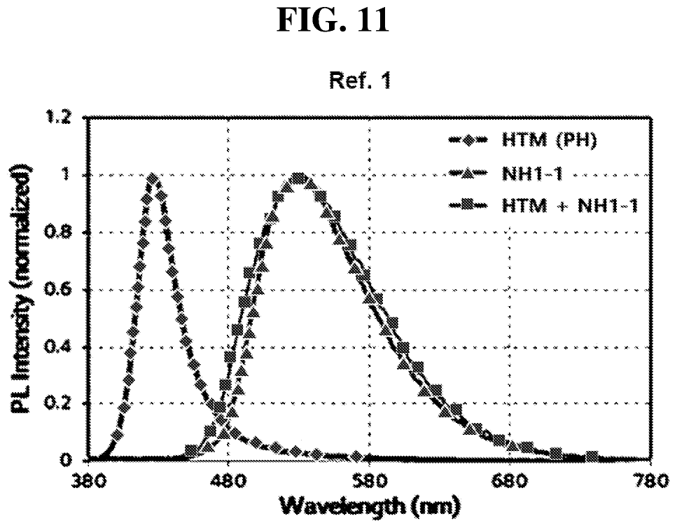

FIG. 10 illustrates a cross-sectional view of an organic light emitting diode having a tandem structure of four emitting parts in accordance with another example embodiment of the present disclosure.

As illustrated in FIG. 10, the OLED D4 in accordance with the present disclosure includes first and second electrodes 510 and 520 facing each other and an emissive layer 530B disposed between the first electrode 510 and the second electrode 520. The emissive layer 530B includes a first emitting part 600A disposed between the first electrode 510 and the second electrode 520, a second emitting part 700B disposed between the first emitting part 600A and the second electrode 520, a third emitting part 800A disposed between the second emitting part 700B and the second electrode 520, a fourth emitting part 900 disposed between the third emitting part 800A and the second electrode 520, a first charge generation layer (CGL1) 690 disposed between the first and second emitting parts 600A and 700B, a second charge generation layer (CGL2) 790 disposed between the second and third emitting parts 700B and 800A, and a third charge generation layer (CGL3) 890 disposed between the third and fourth emitting parts 800A and 900.

The first emitting part 600A includes a first emitting material layer (EML1) 640A. The first emitting part 600A can include at least one of a hole injection layer (HIL) 610 disposed between the first electrode 510 and the EML1 640A, a first hole transport layer (HTL1) 620 disposed between the HIL 610 and the EML1 640A, and a first electron transport layer (ETL1) 680 disposed between the EML1 640A and the CGL1 690. Alternatively, the first emitting part 600A can further include a first electron blocking layer (EBL1) 630 disposed between the HTL1 620 and the EML1 640A and/or a first hole blocking layer (HBL1) 670 disposed between the EML1 640A and the ETL1 680.

The second emitting part 700B includes a second emitting material layer (EML2) 740″. The second emitting part 700B can include at least one of a second hole transport layer (HTL2) 720 disposed between the CGL1 690 and the EML2 740″ and a second electron transport layer (ETL2) 780 disposed between the EML2 740″ and the CGL2 790. Alternatively, the second emitting part 700B can further include a second electron blocking layer (EBL2) 730 disposed between the HTL2 720 and the EML2 740″ and/or a second hole blocking layer (HBL2) 770 disposed between the EML2 740″ and the ETL2 780.

The third emitting part 800A includes a third emitting material layer (EML3) 840A. The third emitting part 800A can include at least one of a third hole transport layer (HTL3) 820 disposed between the CGL2 790 and the EML3 840A and a third electron transport layer (ETL3) 880 disposed between the EML3 840A and the CGL3 890. Alternatively, the third emitting part 800A can further include a third electron blocking layer (EBL3) 830 disposed between the HTL3 820 and the EML3 840A and/or a third hole blocking layer (HBL3) 870 disposed between the EML3 840A and the ETL3 880.

The fourth emitting part 900 includes a fourth emitting material layer (EML4) 940. The fourth emitting part 900 can include at least one of a fourth hole transport layer (HTL4) 920 disposed between the CGL3 890 and the EML4 940, a fourth electron transport layer (ETL4) 980 disposed between the EML4 940 and the second electrode 520, and an electron injection layer (EIL) 990 disposed between the ETL4 980 and the second electrode 520. Alternatively, the fourth emitting part 900 can further include at least one of a fourth electron blocking layer (EBL4) 930 disposed between the HTL4 920 and the EML4 940 and a fourth hole blocking layer (HBL4) 970 disposed between the EML4 940 and the ETL4 980.

The CGL1 690 is disposed between the first emitting part 600A and the second emitting part 700B, the CGL2 790 is disposed between the second emitting part 700B and the third emitting part 800A and the CGL3 890 is disposed between the third emitting part 800A and the fourth emitting part 900. The CGL1 690 includes a first N-type charge generation layer (N-CGL1) 692 disposed adjacently to the first emitting part 600A and a first P-type charge generation layer (P-CGL1) 694 disposed adjacently to the second emitting part 700B. The CGL2 790 includes a second N-type charge generation layer (N-CGL2) 792 disposed adjacently to the second emitting part 700B and a second P-type charge generation layer (P-CGL2) 794 disposed adjacently to the third emitting part 800A. The CGL3 890 includes a third N-type charge generation layer (N-CGL3) 892 disposed adjacently to the third emitting part 800A and a third P-type charge generation layer (P-CGL3) 894 disposed adjacently to the fourth emitting part 900.

Each of the N-CGL1 692, the N-CGL2 792 and the N-CGL3 892 injects electrons to the EML1 640A of the first emitting part 600A, the EML2 740″ of the second emitting part 700B and the EML3 840A of the third emitting part 800A, respectively, and each of the P-CGL1 694, the P-CGL2 794 and the P-CGL3 894 injects holes to the EML2 740″ of the second emitting part 700B. the EML3 840A of the third emitting part 800A and the EML4 940 of the fourth emitting part 900, respectively.

The materials of the HIL 610, the first to fourth HTLs 620, 720, 820 and 920, the first to fourth EBLs 630, 730, 830 and 930, the first to fourth HBLs 670, 770, 870 and 970, the first to fourth ETLs 680, 780, 880 and 980, the EIL 990 and the first to third CGLs 690, 790 and 890 can be identical to corresponding materials with referring to FIGS. 3 and 8.

In the OLED D4, two of the first to fourth emitting parts 600A, 700B, 800A and 900 emits blue color light, another of the first to fourth emitting parts 600A, 700B, 800A and 900 emits green color light, and the rest of the first to fourth emitting parts 600A, 700B, 800A and 900 emits red color light, so that the OLED D4 can implement white (W) emission. Hereinafter, the OLED D4 where the first emitting part 600A emits red color light, the second and fourth emitting parts 700B and 900 emits blue color light and the third emitting part 800A emits green color light will be described in detail.

The EML2 740″ and the EML4 940 can be a blue EML. In this case, each of the EML2 740″ and the EML4 940 can independently a blue EML, a sky-blue EML or a deep-blue EML. Each of the EML2 740″ and the EML4 940 can include a blue host of one or more and a blue dopant (blue emitter). The blue host and/or the blue emitter can be identical to the corresponding materials with referring to FIG. 8. For example, the blue dopant can include at least one of blue phosphorescent material, blue fluorescent material and blue delayed fluorescent material. Alternatively, the blue host and/or the blue emitter in the EML2 740″ can be different from the blue host and/or the blue emitter in the EML4 940 in terms of luminous color and luminous efficiency.

The EML1 640A includes a first red emitting material layer (R-EML1) 650 and a second red emitting material layer (R-EML2) 660 disposed between the R-EML1 650 and the CGL1 690. The R-EML1 650 includes a first N-type host 652, and optionally, a first P-type host 654 and/or a first red dopant (first red emitter) 656. The R-EML2 660 includes a second N-type host 662, and optionally, a second P-type host 664 and/or a second red dopant (second red emitter) 666. The structure, energy level and contents of the first N-type host 652, the first P-type host 654, the first red dopant 656, the second N-type host 662, the second P-type host 664 and the second red dopant 666 can be identical to corresponding materials with referring to FIGS. 3, 4 and 8.

The EML3 840A includes a green host of one or more and a green dopant (green emitter). The structure or the contents of the green host and the green dopant can be identical to corresponding materials with referring to FIG. 8.

The OLEDs D2, D3 and D4 have a tandem structure and includes plural red emitting material layers each of which includes an N-type host with different energy levels and/or electron mobility. Exciton loss can be minimized and exciton formations within the emitting material layers can be induced. The driving voltage of the OLEDs D2, D3 and D4 can be lowered and the luminous efficiency and the luminous lifetime of the OLEDs D2, D3 and D4 can be improved.

### Example 1 (Ex.1): Fabrication of OLED

An organic light emitting diode having two red emitting material layers, a yellow-green emitting material layer and a green emitting material layer are fabricated. A glass substrate onto which ITO (1200 Å) was coated as a thin film was washed and ultrasonically cleaned by solvent such as isopropyl alcohol, acetone and dried at 100° C. oven. The substrate was transferred to a vacuum chamber for depositing emissive layer as the following order:

Hole injection layer (H1 below, 100 Å); hole transport layer (HT below, 80 Å); first red emitting material layer (host (PH below (HOMO: −5.16 eV): Compound NH1-1 of Chemical Formula 4 (LUMO: −2.82 eV)=4:6 by weight, 98 wt %), RD below (2 wt %), 100 Å); second red emitting material layer (host (PH below: Compound NH2-1 of Chemical Formula 6 (LUMO: −3.06 eV)=4:6 by weight, 98 wt %), RD below (2 wt %), 100 Å); yellow-green emitting material layer (host (CBP below: TPBi=5:5 by weight, 75 wt %), YGD below (25 wt %), 100 Å); green emitting material layer (host (CBP below: TPBi=7:3 by weight, 93 wt %), GD below (7 wt %), 300 Å); electron transport layer (TPBi, 220 Å); electron injection layer (Bphen, 200 Å); and cathode (Al).

The fabricated OLED was encapsulated with glass and transferred to a dry box to form a film and then encapsulated with UV-cured epoxy and water getter. The structures of materials of hole injecting material (HI), hole transporting material (HT), P-type host (HT and CBP), red dopant (RD), yellow-green dopant (YGD), green dopant (GD), electron transporting material (TPBi) and electron injecting material (Bphen) are illustrated in the following:

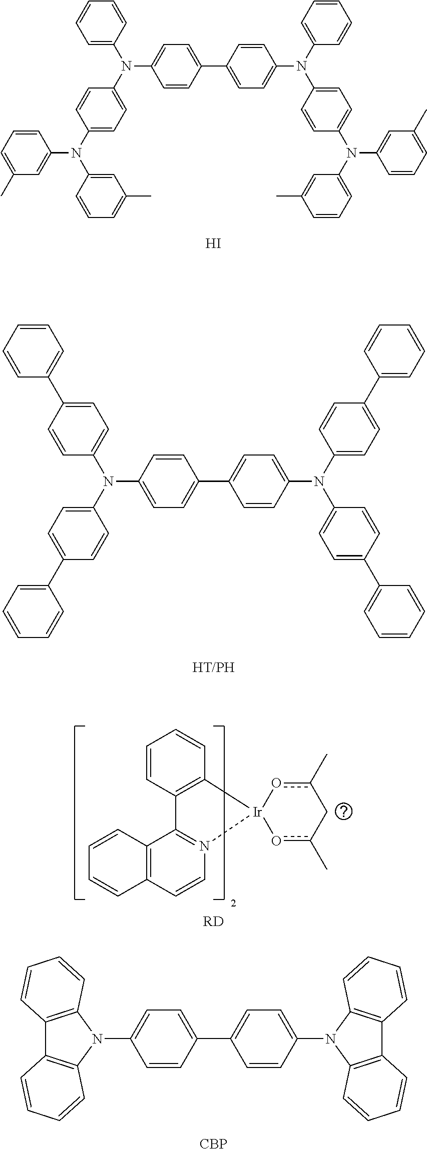

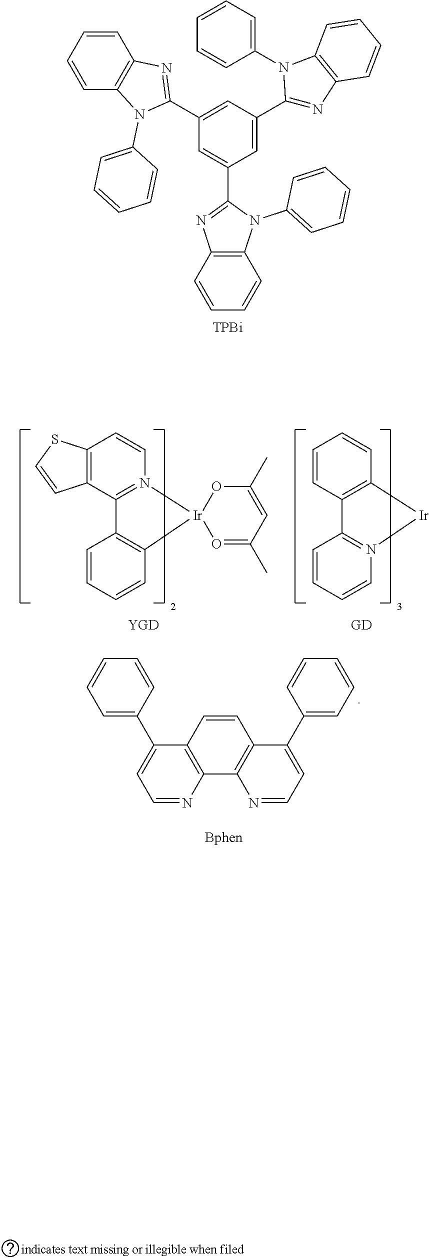

### Examples 2-5 (Ex. 2-5): Fabrication of OLEDs

An OLED was fabricated using the same procedure and the same material as Example 1, except that Compound NH2-2 (LUMO: −3.11 eV, Example 2), Compound NH2-3 (LUMO: −3.05 eV, Example 3), Compound NH2-4 (LUMO: −3.10 eV, Example 4) or Compound NH2-5 (LUMO: −3.08 eV, Example 5) instead of Compound NH2-1 was used as the N-type host in the second red emitting material layer.

### Example 6 (Ex. 6): Fabrication of OLEDs

An OLED was fabricated using the same procedure and the same material as Example 1, except that the first red emitting material layer had a thickness of 50 Å and the second red emitting material layer had a thickness of 150 Å.

### Comparative Example 1 (Ref. 1): Fabrication of OLEDs

An OLED was fabricated using the same procedure and the same material as Example 1, except that the red emitting material layer included only single emitting material layer that included the host (PH: NH1-1=4:6 by weight, 98 wt %) and RD (2 wt %) and had a thickness of 200 Å.

### Comparative Examples 2-6 (Ref. 2-6): Fabrication of OLEDs

An OLED was fabricated using the same procedure and the same material as Comparative Example 1, except that Compound NH2-1 (Comparative Example 2), Compound NH2-2 (Comparative Example 3), Compound NH2-3 (Comparative Example 4), Compound NH2-4 (Comparative Example 5) or Compound NH2-5 (Comparative Example 6) instead of Compound NH1-1 was used as the N-type host in the red emitting material layer.

### Experimental Example 1: Measurement of Luminous Properties of OLEDs

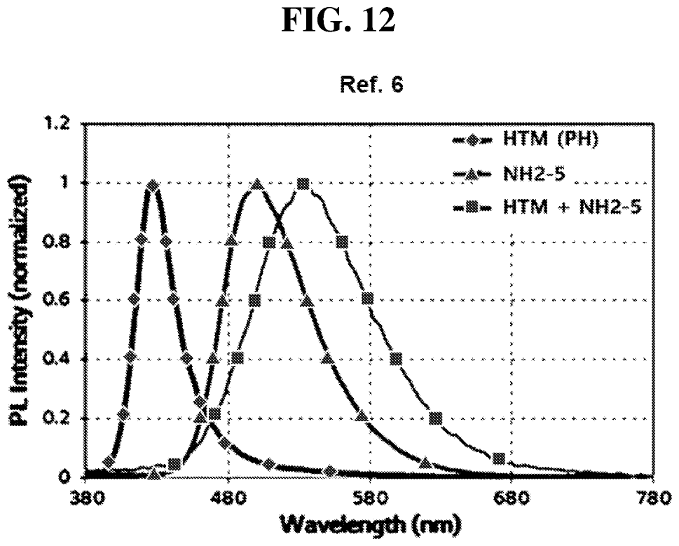

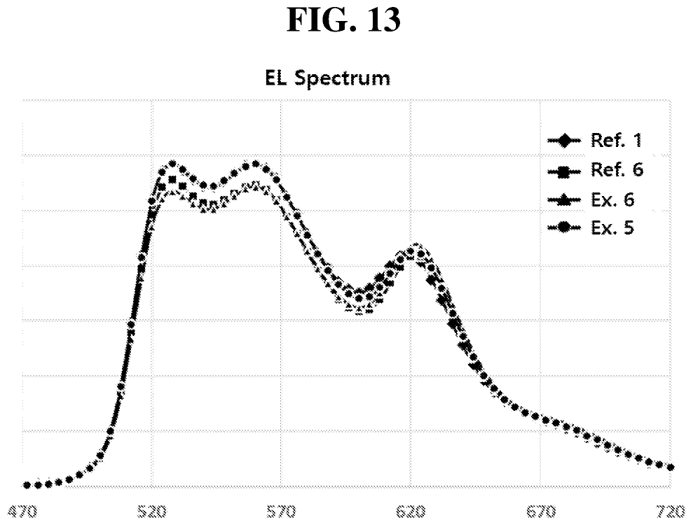

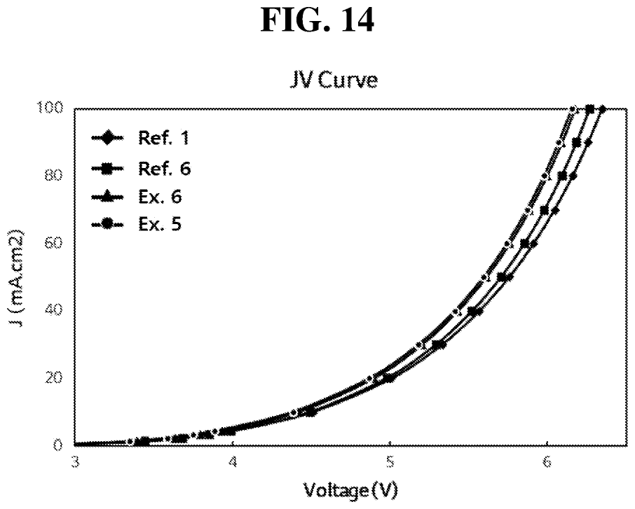

The luminous properties for each of the OLEDs, fabricated in Examples 1 to 6 and Comparative Examples 1 to 6, were measured. Each of the OLEDs, fabricated in Examples 1 to 6 and Comparative Examples 1 to 6 was connected to an external power source and then luminous properties for all the OLEDs were evaluated using a constant current source (KEITHLEY) and a photometer PR650 at room temperature. In particular, the photoluminescence spectrum of the hosts used in Comparative Examples 1 and 6, the driving voltage (V), external quantum efficiency (EQE), lifetime (T₉₅, relative value) of the red light and the green light at which the luminance was reduced to 95% from initial luminance, electroluminescence (EL) spectrum and J−V (current density−voltage) were measured at a current density 10 mA/cm² and 100 mA/cm². The measurement results are indicated in the following Table 1 and FIGS. 11 to 14.

TABLE 1
Luminous Properties of OLED

| | | | | lifetime | |
|---|---|---|---|---|---|
| | V | V | | Red | Green |
| Sample | (10 mA/cm²) | (100 mA/cm²) | EQE | T₉₅ (%) | T₉₅ (%) |
| Ref. 1 | 4.51 | 6.35 | 21.2 | 88 | 112 |
| Ref. 2 | 4.46 | 6.24 | 20.2 | 103 | 160 |
| Ref. 3 | 4.48 | 6.28 | 20.4 | 98 | 130 |
| Ref. 4 | 4.51 | 6.31 | 20.4 | 93 | 142 |
| Ref. 5 | 4.46 | 6.22 | 20.2 | 110 | 175 |
| Ref. 6 | 4.49 | 6.27 | 20.3 | 106 | 190 |
| Ex. 1 | 4.36 | 6.12 | 21.3 | 120 | 175 |
| Ex. 2 | 4.37 | 6.18 | 21.1 | 110 | 145 |
| Ex. 3 | 4.40 | 6.21 | 21.2 | 105 | 160 |
| Ex. 4 | 4.37 | 6.10 | 21.2 | 125 | 170 |
| Ex. 5 | 4.39 | 6.16 | 21.3 | 120 | 210 |
| Ex. 6 | 4.42 | 6.17 | 20.6 | 140 | 210 |

As indicated in Table 1, compared to the OLEDs fabricated in Comparative Examples 1 to 6, in the OLEDs fabricated in Examples 1 to 6, the driving voltage at the current density of 10 mA/cm² and 100 mA/cm² was reduced and the EQE was maintained equivalent level. In addition, compared to the OLEDs fabricated in Comparative Examples 1 to 6, in the OLEDs fabricated in Examples 1 to 6, the lifetime of the red light and the green light were improved significantly. Also, as illustrated in FIG. 11, no exciplex between the hole transporting material and the N-type host was formed when the Compound NH1-1 with relatively shallow (high) LUMO energy level was used as the N-type host. On the contrary, as illustrated in FIG. 12, exciplex between the hole transporting material and the N-type host was formed so that the emission peak at long wavelength was formed when the Compound NH2-5 with relatively deep (low) LUMO energy level was used.

It will be apparent to those skilled in the art that various modifications and variations may be made in the present disclosure without departing from the scope of the disclosure. Thus, it is intended that the present disclosure cover the modifications and variations of the present disclosure provided they come within the scope of the appended claims.

What is claimed is:

1. An organic light emitting diode including:
a first electrode;
a second electrode facing the first electrode; and
an emissive layer disposed between the first electrode and the second electrode, and including an emitting material layer,
wherein the emitting material layer includes:
a first red emitting material layer including a first N-type host; and
a second red emitting material layer disposed between the first red emitting material layer and the second electrode, and including a second N-type host, and
wherein the second N-type host has a lowest unoccupied molecular orbital (LUMO) energy level lower than a LUMO energy level of the first N-type host.

2. The organic light emitting diode of claim 1, wherein the second N-type host has electron mobility larger than an electron mobility of the first N-type host.

3. The organic light emitting diode of claim 1, wherein the LUMO energy level of the second N-type host is lower than the LUMO energy level of the first N-type host by about 0.2 eV to about 0.4 eV.

4. The organic light emitting diode of claim 1, wherein the first N-type host includes an organic compound having the following structure of Chemical Formula 3: 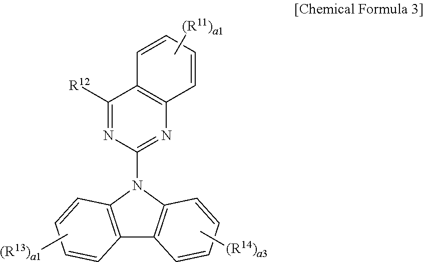
wherein, in the Chemical Formula 3,
R¹¹ is independently an unsubstituted or substituted C₁-C₂₀ alkyl group, an unsubstituted or substituted C₆-C₃₀ aryl group or an unsubstituted or substituted C₃-C₃₀ hetero aryl group, where each R¹¹ is identical to or different from each other when a1 is 2, 3 or 4;
R¹² is hydrogen, an unsubstituted or substituted C₁-C₂₀ alkyl group, an unsubstituted or substituted C₆-C₃₀ aryl group or an unsubstituted or substituted C₃-C₃₀ hetero aryl group;
each of R¹³ and R¹⁴ is independently hydrogen, an unsubstituted or substituted C₆-C₃₀ aryl group or an unsubstituted or substituted C₃-C₃₀ hetero aryl group, where each R¹³ is identical to or different from each other when a2 is 2, 3 or 4 and where each R¹⁴ is identical to or different from each other when a3 is 2, 3 or 4, or
optionally,
two adjacent R¹³ when a2 is 2, 3 or 4 and/or two adjacent R¹⁴ when a3 is 2, 3 or 4 are further linked together to form an unsubstituted or substituted C₆-C₁₀ aromatic ring;
a1 is 0, 1, 2, 3 or 4; and
each of a2 and a3 is independently 0, 1, 2, 3 or 4 where at least one of a2 and a3 is not 0.

5. The organic light emitting diode of claim 4, wherein the first N-type host includes at least one of the following compounds:

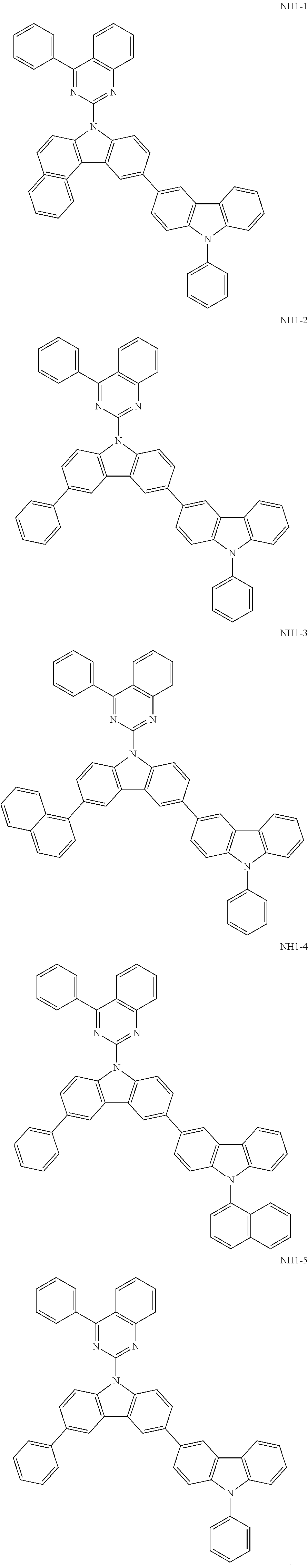

6. The organic light emitting diode of claim 1, wherein the second N-type host includes an organic compound having the following structure of Chemical Formula 5: 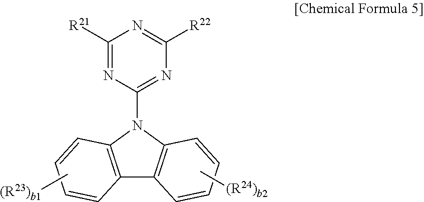
wherein, in the Chemical Formula 5,
each of R²¹ and R²² is independently hydrogen, an unsubstituted or substituted C₁-C₂₀ alkyl group, an unsubstituted or substituted C₆-C₃₀ aryl group or an unsubstituted or substituted C₃-C₃₀ hetero aryl group;
each of R²³ and R²⁴ is independently an unsubstituted or substituted C₁-C₂₀ alkyl group, an unsubstituted or substituted C₆-C₃₀ aryl group or an unsubstituted or substituted C₃-C₃₀ hetero aryl group, where each R²³ is identical to or different from each other when b1 is 2, 3 or 4 and where each R²⁴ is identical to or different from each other when b2 is 2, 3 or 4; and
each of b1 and b2 is independently 0, 1, 2, 3 or 4.

7. The organic light emitting diode of claim 6, wherein the second N-type host includes at least one of the following compounds:

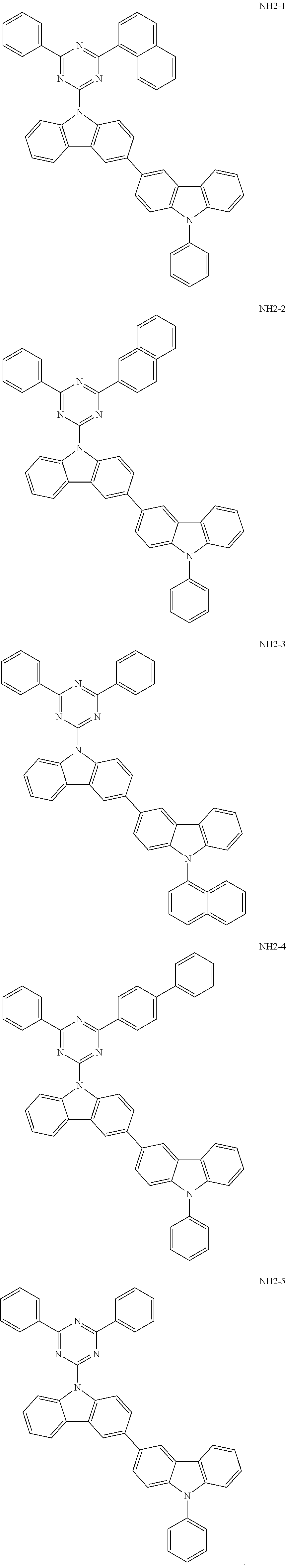

8. The organic light emitting diode of claim 1, wherein the first red emitting material layer further includes a first P-type host and the second red emitting material layer further includes a second P-type host.

9. The organic light emitting diode of claim 8, wherein each of the first P-type host and the second P-type host independently includes an organic compound having the following structure of Chemical Formula 1: 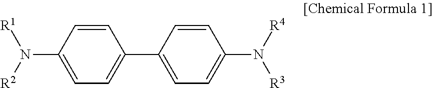
wherein, in the Chemical Formula 1,
each of R¹, R², R³ and R⁴ is independently an unsubstituted or substituted C₆-C₃₀ aryl group or an unsubstituted or substituted C₃-C₃₀ hetero aryl group.

10. The organic light emitting diode of claim 9, wherein each of the first P-type host and the second P-type host independently includes at least one of the following compounds:

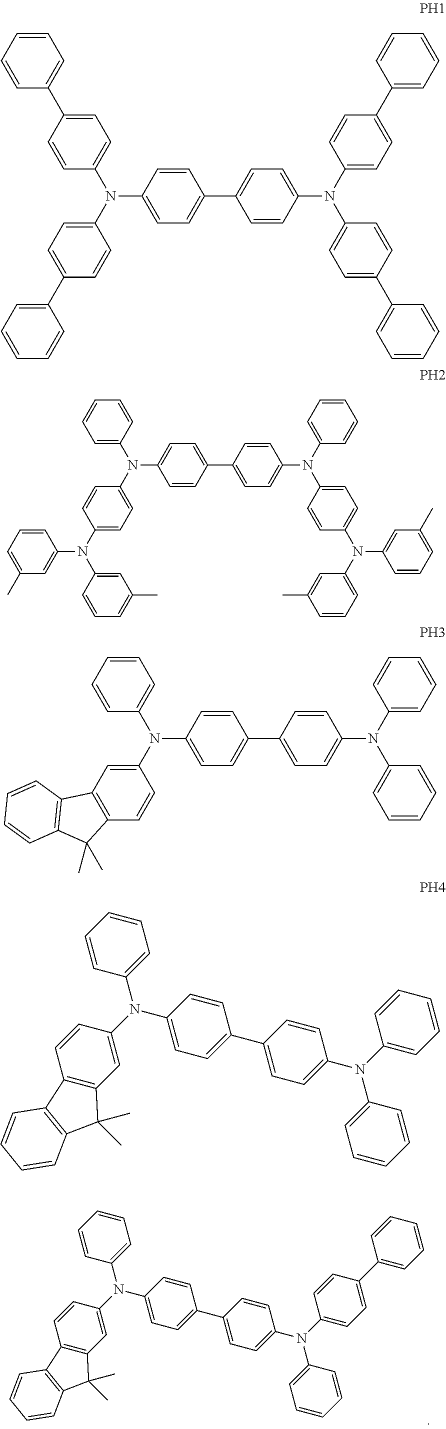

11. The organic light emitting diode of claim 8, wherein a difference between the LUMO energy level of the first N-type host and a highest occupied molecular orbital (HOMO) energy level of the first P-type host and/or the second P-type host is between about 2.3 eV and about 2.5 eV.

12. The organic light emitting diode of claim 8, wherein a difference between the LUMO energy level of the second N-type host and a highest occupied molecular orbital (HOMO) energy level of the first P-type host and/or the second P-type host is between about 1.8 eV and about 2.2 eV.

13. The organic light emitting diode of claim 8, wherein contents of the first N-type host is larger than contents of the first P-type host in the first red emitting material layer and contents of the second N-type host is larger than contents of the second P-type host in the second red emitting material layer.

14. The organic light emitting diode of claim 1, wherein the first red emitting material layer has a thickness smaller than or equal to a thickness of the second red emitting material layer.

15. The organic light emitting diode of claim 1, wherein the emissive layer has a single emitting part.

16. The organic light emitting diode of claim 1, wherein the emissive layer includes:
a first emitting part disposed between the first electrode and the second electrode, and including a first emitting material layer;
a second emitting part disposed between the first emitting part and the second electrode, and including a second emitting material layer; and
a first charge generation layer disposed between the first emitting part and the second emitting part.

17. The organic light emitting diode of claim 16, wherein one of the first emitting material layer and the second emitting material layer includes the first red emitting material layer and the second red emitting material layer.

18. The organic light emitting diode of claim 16, wherein the second emitting material layer includes:
a first layer disposed between the first charge generation layer and the second electrode; and
a second layer disposed between the first layer and the second electrode, and
wherein one of the first layer and the second layer includes the first red emitting material layer and the second red emitting material layer.

19. The organic light emitting diode of claim 18, wherein the first layer includes the first red emitting material layer and the second red emitting material layer.

20. The organic light emitting diode of claim 18, wherein the second emitting material layer further includes a third layer disposed between the first layer and the second layer.
